(19) United States
(12) Patent Application Publication
(10) Pub. No.: US 2026/0062607 A1
(43) Pub. Date: Mar. 5, 2026

(54) TWO-DIMENSIONAL LATTICE CONFINED SINGLE-MOLECULE-LIKE AGGREGATES

(71) Applicant: Purdue Research Foundation, West Lafayette, IN (US)

(72) Inventors: Letian DOU, West Lafayette, IN (US); Kang WANG, Beijing (CN)

(21) Appl. No.: 19/314,963

(22) Filed: Aug. 29, 2025

Related U.S. Application Data
(60) Provisional application No. 63/688,461, filed on Aug. 29, 2024.
(60) Provisional application No. 63/691,733, filed on Sep. 6, 2024.

(51) Int. Cl. C09K 11/06; H01S 5/125; H01S 5/36; H10K 85/50

(52) U.S. Cl. CPC C09K 11/06; H01S 5/36; H10K 85/50; C09K 2211/188; H01S 5/125

(57) ABSTRACT

A two-dimensional (2D) perovskite superlattice and methods of formation are disclosed herein. The perovskite superlattice includes a layered structure with alternating inorganic (lead-bromide sheets) and organic components (FBTT, FBTP, PBTP, and BBTP) that creates a reversed type-I band alignment. The superlattice structure enables the formation of SMA, which combine properties of both single molecules and aggregates.

### PRIORITY

This application claims the benefit of priority to U.S. Provisional Patent Application Ser. No. 63/688,461, filed Aug. 29, 2024, and 63/691,733, filed Sep. 6, 2024, each of which is incorporated herein by reference in its entirety.

### GOVERNMENTAL RIGHTS

This invention was made with government support under 2131608 ECCS and 2143568 DMR awarded by the National Science Foundation and under DE-EE0009519 and DE-SC0022082 awarded by the Department of Energy. The government has certain rights in the invention.

### BACKGROUND

Intermolecular distance largely determines the optoelectronic properties of organic matter. Conventional organic luminescent molecules are commonly used either as aggregates or as single molecules that are diluted in a foreigner matrix. However, the manner in which such molecules behave between the aggregation state and the dilution state remains to be investigated.

### SUMMARY

The disclosure relates to perovskite two-dimensional (2D) superlattices (SLs) that contain FBTT, FBTP, PBTP, and/or BBTP. FBTT stands for 2-(5-(7-(9,9-dimethyl-9H-fluoren-2-yl)benzo[c][1,2,5]thiadiazol-4-yl)thiophen-2-yl)ethan-1-ammonium bromide. The FBTT molecule is based on the repeating unit of a bright green-emitting polymer called poly(9,9-dioctylfluorene-alt-benzothiadiazole) (F8BT), with modifications to ensure it can be accommodated in the perovskite lattice. Specifically, FBTT includes a thienyl group as a linker connecting the chromophore core with the ammonium tail, which then ionically bonds with the lead-halide matrix of the perovskite structure. FBTP stands for 2-(4-(7-(9,9-dimethyl-9H-fluoren-2-yl)benzo[c][1,2,5]thiadiazol-4-yl)phenyl)ethan-1-ammonium bromide. Like FBTT, FBTP is also based on the repeating unit of the bright green-emitting polymer F8BT. However, FBTP uses a phenyl group as a linker connecting the chromophore core with the ammonium tail, which then ionically bonds with the lead-halide matrix of the perovskite structure. PBTP stands for 2-(4-(7-(o-tolyl)benzo[c][1,2,5]thiadiazol-4-yl)phenyl)ethan-1-ammonium bromide. PBTP is a sky-blue emitter developed by replacing the fluorene unit in FBTP with a weaker donor (tolyl group). BBTP stands for 8-bromobenzo[1,2-c:4,5-c′]bis([1,2,5]thiadiazole-4-yl)phenyl)ethan-1-ammonium bromide. BBTP is a red emitter created by substituting the benzothiadiazole group in FBTP with a stronger acceptor (benzo[1,2-c:4,5-c′]bis([1,2,5]thiadiazole). The chemical structures for these organic emitters have been confirmed by NMR and high-resolution mass spectrometry (HR-MS).

The perovskite superlattice includes a layered structure with alternating inorganic (lead-bromide sheets) and organic components (FBTT, FBTP, PBTP, and BBTP) that creates a reversed type-I band alignment, which is used for efficient organic emission. This superlattice structure enables the formation of SMA, which combine properties of both single molecules and aggregates. This arrangement allows for high photoluminescence quantum yields similar to single molecules, while also providing the benefits of strong alignment and dense packing characteristic of aggregates.

### DESCRIPTION OF THE DRAWINGS

The drawings illustrate generally, by way of example, but not by way of limitation, various embodiments discussed herein.

FIG. 1 shows a schematic illustration for different scenarios of molecular emitters with varied intermolecular distances.

FIGS. 2A-2H show single-molecule behavior of molecular emitters in perovskite 2D SLs.

FIGS. 3A-3K show molecular insights into the rotational and vibrational behaviors of organic molecules confined in 2D SLs.

FIGS. 4A-4D show single-molecule behaviors of other organic emitters in 2D SLs.

FIGS. 5A-5K show single-molecule-like aggregate behaviors of organic emitters in 2D SLS.

FIGS. 6A-6C show DFT and TDDFT simulations on the energy level of molecular emitters.

FIGS. 7A-7B show the extracted azimuthal distribution of GIWAXS intensity for 2D perovskites at a typical q near 0.5 A⁻¹ (dashed rings in FIGS. 2B and 2F).

FIGS. 8A-8C show FBTP emitters confined in 2D SLs with tunable inorganic sublattices.

FIGS. 9A-9D show the AFM surface morphology study on both molecular aggregates and 2D perovskites thin-film samples.

FIGS. 10A-10C show 2D perovskite nanocrystals and their corresponding PL spectra.

FIGS. 11A-11B show a schematic illustration of MD simulations on organic molecules rotation within perovskite lattice.

FIGS. 12A-12B show the packing styles of organic molecules within 2D SLs.

FIGS. 13A-13E show the structural characterizations and UV-vis spectra of PBTP and BBTP-based thin films.

FIGS. 14A-14D show streak camera results at different temperatures.

FIGS. 15A-15G show lasing characterization on FBTP monomer and FBTP aggregates.

FIG. 16 shows a device, in accordance with some examples.

FIG. 17 illustrates an example of an electronic device in accordance with some embodiments.

FIGS. 18A-18F show examples of organic molecular emitters in accordance with some embodiments.

### DESCRIPTION

Reference will now be made in detail to certain embodiments of the disclosed subject matter. While the disclosed subject matter will be described in conjunction with the enumerated claims, it will be understood that the exemplified subject matter is not intended to limit the claims to the disclosed subject matter.

A 2D hybrid materials is introduced herein that combines inorganic and components in a layered superlattice structure. In particular, organic molecular emitters are confined between inorganic sheets, forming a periodic superlattice structure with a precisely controlled spacing. The structure forms a new phase of molecular aggregate that forms in a 2D hybrid perovskite superlattice with a near-equilibrium distance, referred to herein as a single-molecule-like aggregate (SMA) so that the organic emitters are in close proximity but remain electronically isolated from one another due to the presence of the inorganic layers. The detailed photophysical properties and the role of the inorganic sublattice in enabling the SMA phase are described in subsequent paragraphs.

The organic molecular emitters suitable for incorporation into the superlattice may generally include cationic species with a conjugated chromophore core, a linker group, and an ammonium or other cationic tail. The chromophore core may include a variety of aromatic or heteroaromatic systems, provided the overall molecular width and shape allow for accommodation within the inorganic lattice pocket. The molecular width and length are typically limited by the spacing of the inorganic sheets, and molecules that are too large or too wide may not be accommodated. In some embodiments, the organic cation may include from one to six repeat units of a heteroaromatic group (e.g., thiophene, pyrrole, furan, or pyridine), provided the overall dimensions are compatible with the lattice. The linker group may be selected to modulate the planarity and rotational freedom of the molecule, which in turn affects aggregation and emission properties. Excessive planarity can promote strong π-π stacking and aggregation-caused quenching (ACQ), so the presence of substituents (e.g., methyl, ethyl) or twisted backbones may be used to reduce planarity and maintain efficient emission. The ammonium tail provides ionic bonding to the inorganic sublattice and may be separated from the chromophore core by a variable-length alkyl or aryl chain, provided steric crowding is avoided. The distance between the ammonium group and the chromophore core can be varied, but if too short, steric crowding may prevent proper incorporation. The presence of electron-donating or electron-withdrawing substituents on the chromophore or linker can be used to tune the energy levels and emission wavelength of the emitter. Mixtures of different organic emitters may also be incorporated, provided they are compatible in size and charge. The counterion associated with the organic cation may typically be a halide, but other anions may be used if compatible with the lattice formation.

The inorganic sublattice is not limited to lead-halide perovskites. Other metal halides, such as tin, germanium, or mixed-metal halides, may be used, as well as alternative layered materials such as transition metal dichalcogenides or oxides, provided the lattice spacing and charge balance are suitable for accommodating the organic cations. The choice of metal and halide can be used to tune the pitch of the lattice and the resulting photophysical properties. In some embodiments, the inorganic lattice may include tin-lead alloys, silver-bismuth combinations, or other layered materials, such as transition metal dichalcogenides (e.g., MoSe₂, WS₂) or layered metal oxides, provided the lattice parameters and energy level alignment are compatible with the organic cation. The choice of metal and halide can be used to tune the pitch of the lattice and the resulting photophysical properties. Doping or alloying of the inorganic sublattice is also possible to further modulate the structure and properties. The thickness and crystallinity of the inorganic layers can be controlled by processing conditions and may affect the overall stability and emission characteristics of the superlattice.

While a wide range of organic and inorganic components can be used, some limitations may exist to these components. Organic emitters that are too large or too planar may not fit within the lattice or may aggregate too strongly, leading to quenching of emission. Inorganic sublattices with incompatible spacing or charge balance may not form stable superlattice structures. Processing conditions that lead to rapid solvent evaporation or insufficient annealing may result in poor crystallinity or phase separation. Negative examples include organic cations with excessive planarity or strong a-z stacking propensity, such as those with thienyl linkers or extended conjugation, which tend to aggregate and exhibit ACQ rather than the desired SMA phase. Examples of such negative structures are provided in the positive and negative examples below. In addition, processing conditions that lead to rapid solvent evaporation, insufficient annealing, or poor solubility of the organic cation may result in poor crystallinity, phase separation, or failure to form the superlattice structure. The approach may be extended to other dimensionalities, such as one-dimensional or three-dimensional hybrid lattices, provided the structural and energetic requirements are met. The approach may be extended to other dimensionalities, such as one-dimensional or three-dimensional hybrid lattices, provided the structural and energetic requirements are met. For example, ID chain structures or 3D frameworks may be used as the inorganic template, provided the organic cation can be accommodated and the desired photophysical properties are achieved.

In more detail, a perovskite is a type of crystalline material with a specific atomic structure, such as hybrid organic-inorganic materials that combine organic molecules with inorganic components in a crystalline lattice structure. Specifically, the perovskites discussed herein are lead halide perovskites, which consist of lead and halide ions (in this case, bromide) forming the inorganic framework. A perovskite superlattice is a 2D layered structure where inorganic perovskite sheets alternate with layers of organic molecules, in particular the superlattice is composed of lead-bromide sheets with a pitch of approximately 6 Å. By implementing 2D superlattices, the organic emitters are held in proximity but remain electronically isolated, resulting in a near unity photoluminescence quantum yield, akin to that of single molecules. Moreover, the emitters within the perovskite superlattices demonstrate strong alignment and dense packing resembling aggregates, allowing for the observation of robust directional emission, significantly enhanced radiative recombination, and efficient lasing.

Molecular dynamics simulation together with single-crystal structure analysis indicate the role of the internal rotational and vibrational degrees of freedom of the molecules in the 2D lattice for creating the exclusive SMA phase. The SMA phase is further characterized by a combination of high photoluminescence quantum yield (PLQY), directional emission, and ultrafast radiative recombination, as supported by both experimental and computational studies.

The PLQY of the superlattice materials is typically in the range of 10% to 90%, depending on the choice of organic emitter and the degree of aggregation or isolation achieved. In some cases, PLQY values above 90% have been observed (e.g., 92.8% for FBTP 2D SLs). The emission wavelength can be tuned from approximately 450 nm (blue) to 700 nm (red) by selection of the organic emitter and adjustment of the inorganic sublattice pitch. Radiative recombination lifetimes are generally in the range of 50 picoseconds to several nanoseconds, with ultrafast components below 100 picoseconds observed in certain superlattice systems. Thin film thicknesses can be controlled from about 20 nm to about 1000 nm, and single crystals with lateral dimensions up to several millimeters have been grown. The emission wavelength is primarily determined by the energy levels of the organic emitter, but can also be influenced by the pitch of the inorganic sublattice. Radiative recombination lifetimes are generally in the picosecond to nanosecond range, similar to those of isolated organic emitters. The materials exhibit robust emission properties across a range of temperatures and under various excitation intensities. Environmental factors such as humidity and oxygen may affect the stability of the superlattice, but the dense packing of the organic layer can provide some protection to the inorganic sublattice.

The band alignment between the organic and inorganic components is typically of the reversed type-I configuration, which enables efficient energy transfer and emission from the organic layer. Electronic isolation of the organic emitters is achieved by the presence of the inorganic sheets, which suppresses intermolecular interactions that would otherwise lead to aggregation-caused quenching. Charge transport in the superlattice is primarily through the inorganic layers, with the organic emitters acting as electronically isolated luminescent centers. The interlayer spacing (pitch) can be tuned from approximately 5 Å to approximately 8 Å by varying the halide composition or by selecting different metal cations. The orientation and packing of the organic emitters may be characterized by X-ray diffraction, grazing-incidence wide-angle X-ray scattering, and microscopy techniques. Polymorphism may occur under different processing conditions, leading to alternative packing motifs. Thin films typically have thicknesses ranging from about 20 nm to about 1000 nm, and surface morphology can be controlled by spin-coating parameters and annealing conditions.

The superlattice materials exhibit enhanced photostability compared to conventional 2D perovskites, with reduced degradation under continuous ultraviolet irradiation. For example, after 100 hours of UV exposure at 0.31 W/cm², the absorbance at the excitonic peak of the superlattice films remained above 80% of the initial value, whereas conventional PEA-based 2D perovskites degrade to below 50% under the same conditions. Thermal stability is also improved due to the robust ionic interactions between the organic cations and the inorganic sublattice. The materials are generally stable under ambient conditions, and encapsulation is not strictly required for short-term device operation, although encapsulation may be beneficial for long-term stability in practical applications. The superlattice films can be stored in air for at least several weeks without significant loss of photoluminescence intensity, and device operation has been demonstrated for over 100 hours without encapsulation under laboratory conditions. Thermal stability tests indicate that the superlattice films retain more than 90% of their initial photoluminescence intensity after heating at 100° C. for 1 hour in air. The materials are stable under relative humidity up to 50% for at least 24 hours, with only minor changes in emission intensity. For long-term device operation or storage in high-humidity environments, encapsulation with a thin polymer or glass layer is recommended to further enhance stability.

The design of 2D perovskite lattices includes inorganic lead-bromide sheets with about a 6 Å pitch that houses organic molecules. This structure creates a reversed type-I band alignment, enabling efficient organic emission FBTT and FBTP molecules based on the F8BT polymer core, as well as PBTP for sky-blue and BBTP for red emissions, demonstrating the color tunability of the system.

Molecular behavior, molecular dynamics simulations, and single-crystal structure analyses reveals that FBTT molecules are more planar and exhibit stronger intermolecular interactions, while FBTP molecules are less planar and behave more like single molecules. FBTP 2D SLs demonstrated a 92.8% photoluminescence quantum yield (PLQY), which is comparable to that of monomers (95.7%). Additionally, the SMA system exhibited directional emission centered around 50° for FBTP SLs and ultrafast radiative recombination with lifetimes below 100 picoseconds. FBTP 2D SLs showed a low lasing threshold of 0.80 μJ/cm2 and a high power factor (p2D=11.22), surpassing the performance of monomers (pmon=1.70). These results indicate SMA systems may be used for advanced photonic applications. The SMA approach effectively overcomes the challenge of aggregation-caused quenching (ACQ) and is distinct from aggregation-induced emission (AIE). Furthermore, the materials demonstrate improved photostability compared to other 2D perovskites. The photostability of the 2D SLs was evaluated under continuous UV irradiation, showing significantly less degradation in absorbance at the excitonic peak compared to conventional PEA-based 2D perovskites. The improved stability is attributed to the robust ionic interactions between the bulky organic cations and the inorganic sublattice.

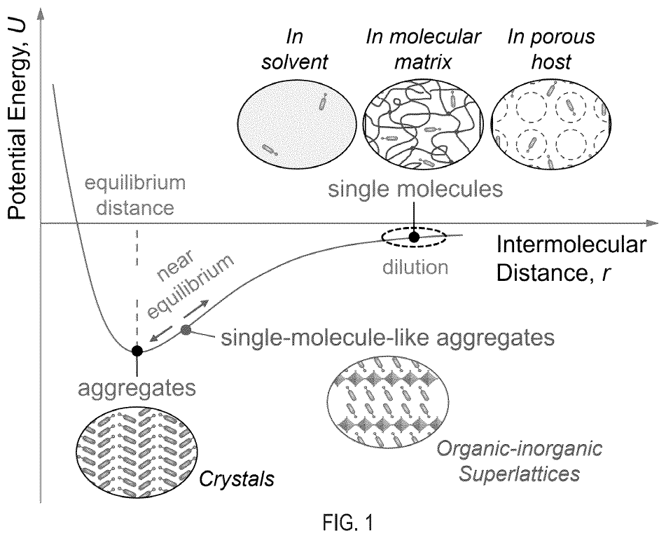

FIG. 1 shows a schematic illustration for different scenarios of molecular emitters with varied intermolecular distances. Organic crystals that demonstrate an intermolecular distance at the equilibrium point of 3-5 Å are one of the most stable aggregated phases and have the lowest potential energy. In this equilibrium state, organic molecules generally exhibit strong intermolecular interactions (e.g., π-π stacking, energy transfer, charge transfer, self-absorption, etc.), which result in a large drop in PLQY. This phenomenon is known as ACQ, which is a major restriction for the practical use of aggregated emitters. An effective strategy to alleviate ACQ was to weaken or eliminate intermolecular interactions by spatially disengaging the emitters far away from each other (>10 Å), such as by dissolving them in solvents, diluting them in a foreigner matrix, embedding them into porous hosts, or growing macrocycle-hosts-based supramolecular single crystals.

These well-isolated single molecules lead to a dilution state with single-molecule behaviors that have allowed efficient emission and set the foundation for organic light-emitting diodes (OLED), lasers, and many other optoelectronic applications. Nonetheless, rare reports exist on organic emitters with an intermolecular distance between the equilibrium and dilution states, and their behaviors have received limited research attention.

2D layered hybrid perovskites combine the advantages of both organic and inorganic components. These unique 2D organic-inorganic SLs offer a platform to investigate the behaviors of organic emitters near equilibrium state because the inorganic sheets intrinsically demonstrate a square lattice with a about 6 Å pitch to house organic molecules, which is potentially sufficient to modulate or suppress intermolecular interactions. However, harnessing the inorganic sublattice to tune intermolecular interactions, molecular packing, and emission properties of organic molecules is largely unexplored and the range of organic molecular emitters that can be incorporated into layered perovskites is rather limited, and their PLQYs are often low (typically below 10%).

Accordingly, a new phase of molecular aggregates, referred to as an SMA is achieved near equilibrium state by combining a 2D inorganic sublattice with suitably tailored organic chromophores. Within this hybrid SL, the behavior of organic emitters closely resembles that of individual single molecules, as evidenced by their similar emission wavelengths and lifetimes as well as near-unity PLQYs. Theoretical and experimental investigations highlight the role of backbone dihedrals within the organic emitter in maintaining this single-molecule behavior. Notably, despite exhibiting single-molecule-like properties, the strong alignment and close packing of organic molecules within the 2D SLs resulted in intense directional emission, ultrafast radiative recombination, and efficient lasing, which are linked to the traits of ordered molecular ensembles or aggregates. The SMA concept is not limited to the specific organic emitters described herein, but may be extended to a wide range of organic cations with appropriate structural features, such as backbone twist and conjugation, that enable electronic isolation within the perovskite lattice. Examples include, but are not limited to, benzothiadiazole, benzobisthiadiazole, benzo[d][1,2,3]triazole, quinoxaline, and isoindoline-dione derivatives.

### SMA Materials Design

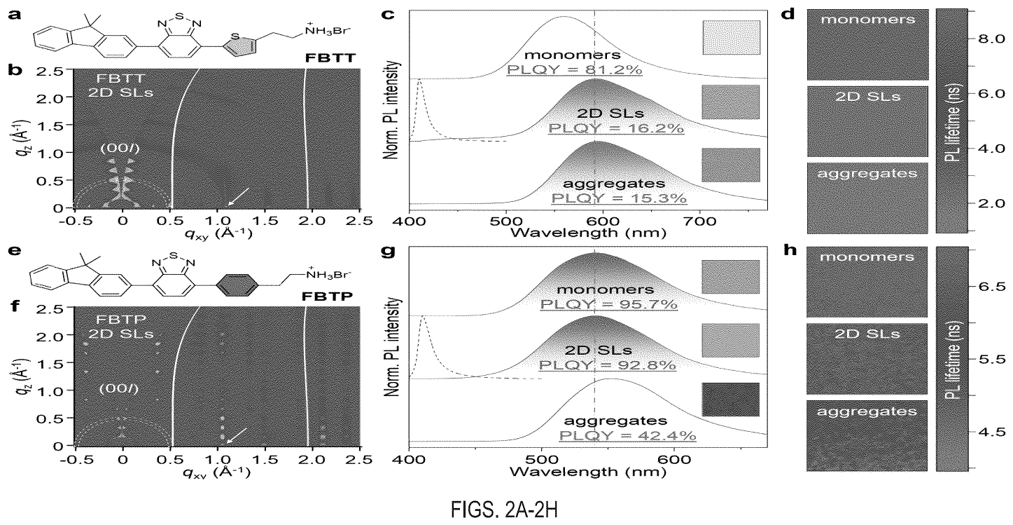

FIGS. 2A-2G show single-molecule behavior of molecular emitters in perovskite 2D SLs. Two organic molecular emitters, FBTT (FIG. 2A) and FBTP (FIG. 2E) are shown and incorporated into the 2D perovskite lattices. The synthetic procedures of the organic molecules are detailed in more detail below. The chromophore core was adapted from the repeating unit of a bright green-emitting polymer F8BT. The alky chain length was cut to one carbon to ensure that the F8BT can be accommodated in the perovskite lattice. Linkers, such as thienyl and phenyl groups, were further introduced to connect the chromophore core with the ammonium tail and then ionically bonded with the lead-halide matrix.

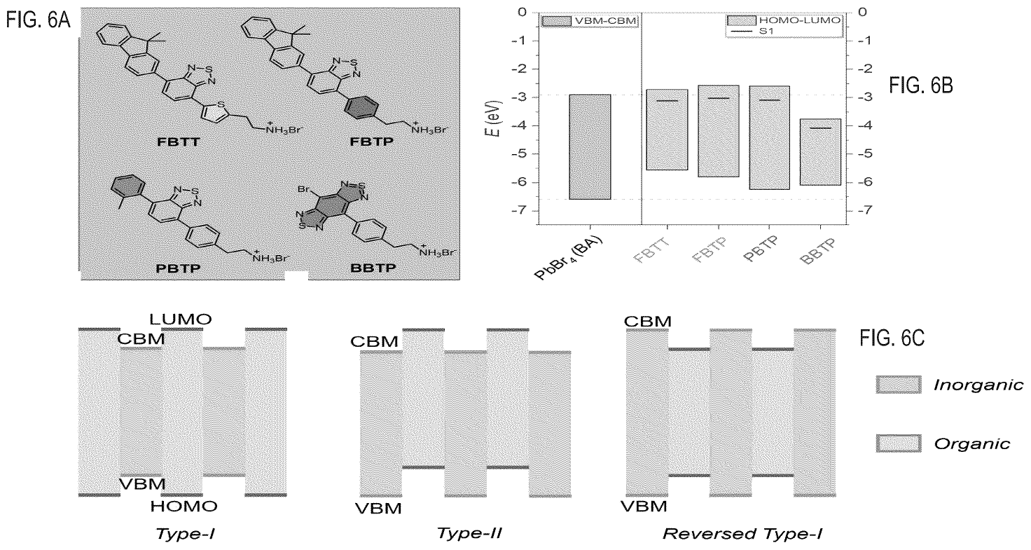

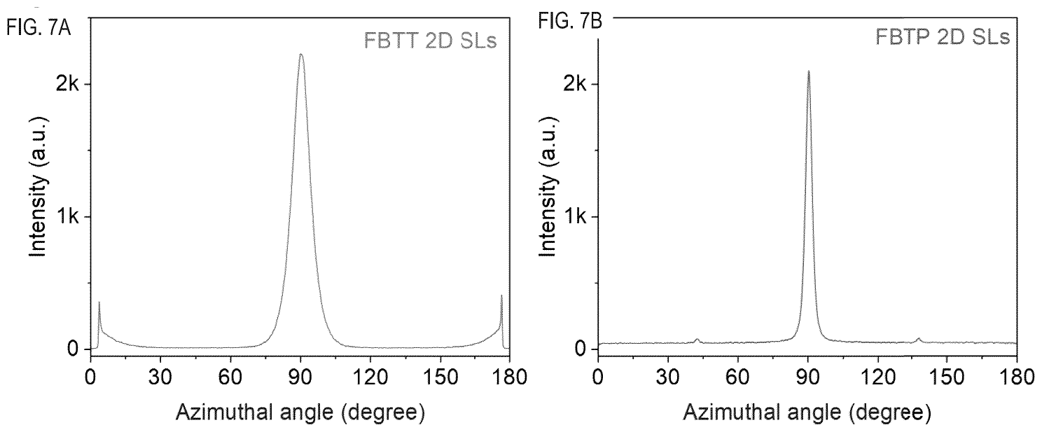

Lead-bromide was selected as the inorganic framework to construct a reversed type-I band alignment for organic compounds to emit efficiently, which is confirmed by density functional theory (DFT) and time-dependent DFT (TDDFT) simulation shown in FIGS. 6A-6C. Thin-film studies on the aggregates (neat organic emitters), 2D SLs (organic emitter-incorporated perovskites), and isolated monomers (2 wt % organic emitters doped PMMA films) were undertaken. Grazing-incidence wide-angle X-ray scattering (GIWAXS) and X-ray diffraction (XRD) characterizations verify that both FBTT and FBTP were successfully incorporated, forming a layered perovskite structure as shown in FIGS. 2B, 2F and FIGS. 7A-7B. The sharp UV-vis peak around 400 nm and the nearby shoulder peak from 2D SLs films (FIGS. 2G, 2H) below can be indexed to the excitonic peak of perovskites and organic emitters, respectively, further supporting the formation of 2D perovskites. The dashed curves in FIGS. 2C, 2G are the PL spectra of (PEA)₂PbBr₄ (PEA is phenylethylammonium), which implies the emission feature of 2D lead-bromide lattice. The inset in FIGS. 2C, 2G are PL images of corresponding thin film samples, and all the image scales are 10 μm×10 μm. The scale bars of all FLIM images in shown in FIGS. 2D, 2H are 50 μm×50 μm.

The PL spectrum of FBTT SLs (peaked at about 594 nm in FIG. 2C) is similar to that of its aggregates and red-shifted compared with its monomer state (PL peak at 559 nm). This red shift is usually ascribed to the intermolecular interaction, especially π-π stacking, induced bandgap narrowing. In contrast, the PL spectrum of FBTP SLs (peaked at about 540 nm in FIG. 2H) is similar to the FBTP monomers and clearly blue-shifted compared with the aggregates (peaked at 553 nm). The inset PL images in FIGS. 2C, 2G further support the above results. The absence of perovskite emission in the profiles in FIGS. 2C, 2G in both FBTT and FBTP SLs substantiates the fact that both 2D SLs are subject to a reversed type-I band alignment. Moreover, the FBTT SLs and aggregates appear to have a similar PLQY of about 15%, which is much lower than its monomer (PLQY=81.2%). This can be explained by the ACQ effect. Surprisingly, the ACQ effect is absent in the FBTP SLs sample, which features a much higher PLQY (92.8%) than that of its aggregates (42.4%). Such a high PLQY is very close to that of its monomers (PLQY=95.7%). These results suggest that the FBTT molecules in perovskites behave more like aggregates, while the FBTP molecules in perovskites behave like single molecules.

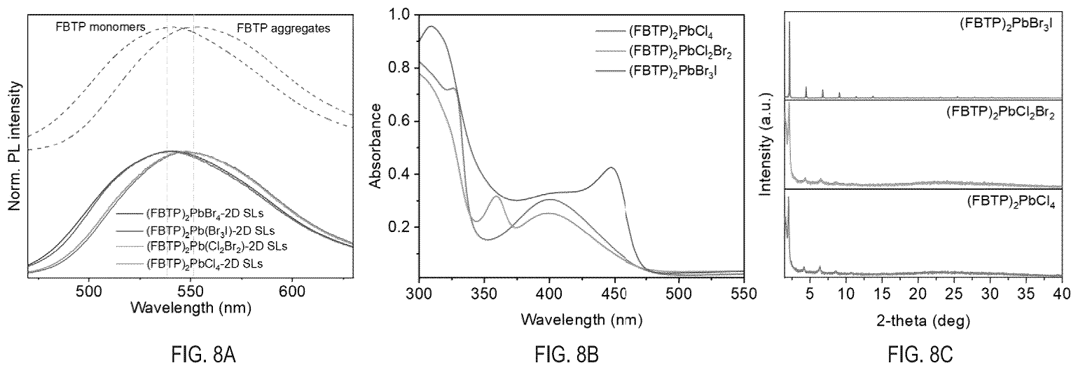

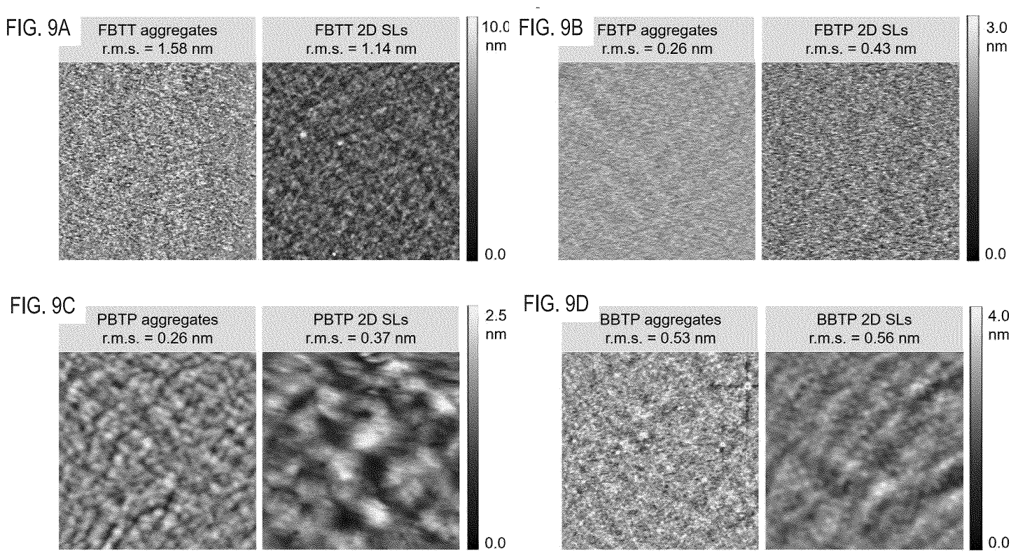

Fluorescence lifetime imaging microscopy (FLIM) measurements show that FBTT SLs manifest similar PL lifetime as its aggregates (FIG. 2D), which is significantly shorter than that of the FBTT monomer, again validating the aggregation behavior of FBTT within the perovskite SLs. The PL lifetime of FBTP SLs matches well with its monomer case (FIG. 2H). It should be noted that the pitch size of the inorganic square lattice can be fine-tuned by introducing different halides, such as chlorine (CI) or iodine (I), which would enable different behaviors of organic emitters. After mixing with I, the inorganic sublattice slightly expands, and the inter-emitter distance increases towards the dilution state. Consequently, the single molecule behaviors are maintained as evidenced by an identical PL emission peak as shown in FIGS. 8A-8C to that of single molecules and pure bromide case. Whereas the incorporation of CI constrains the inorganic sublattice and the organic emitter is brought even closer towards the equilibrium state, thus leading to a similar PL emission as that of aggregates as shown in FIGS. 8A-8C. Furthermore, FBTT and FBTP yielded 2D SLs thin films exhibiting similar surface morphology and thickness as shown in FIGS. 9A-9D.

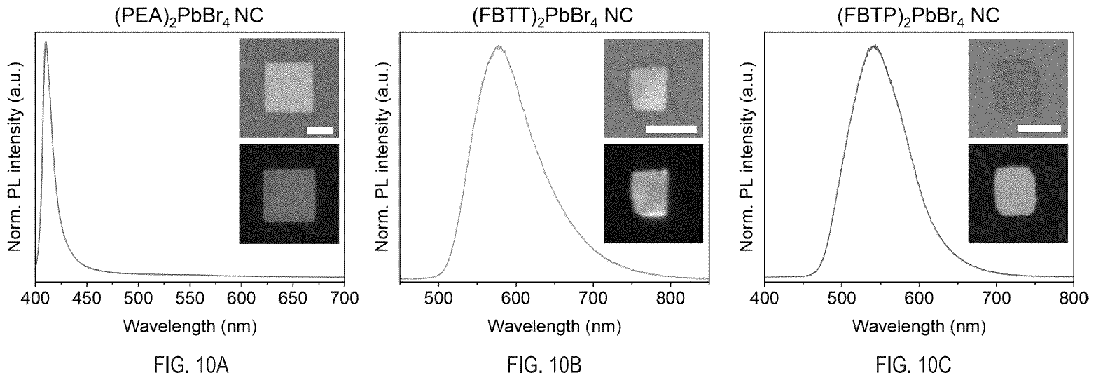

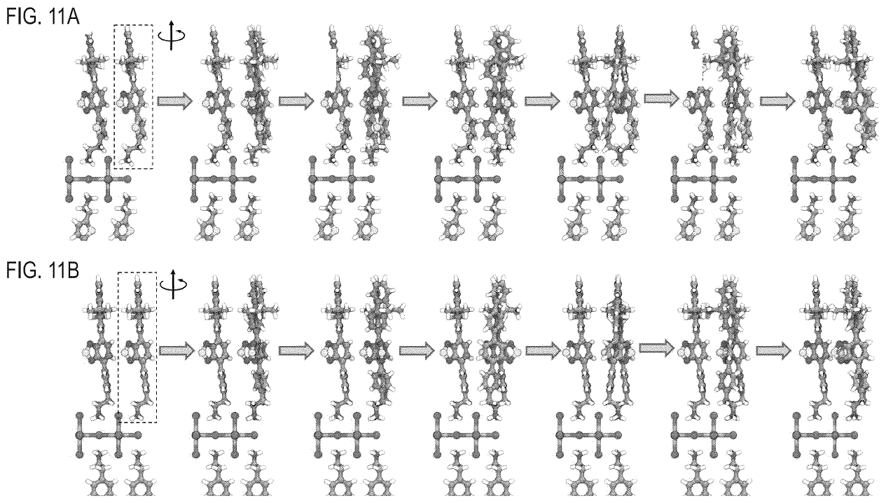

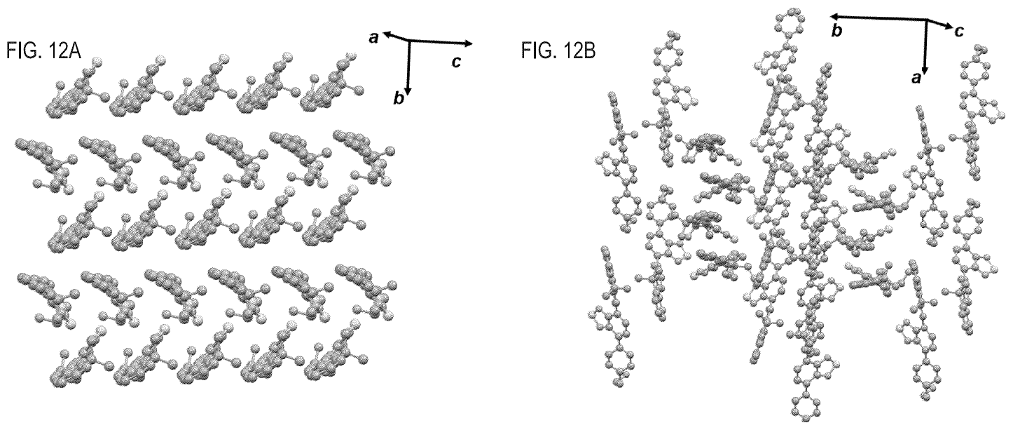

And the emission spectra of single-crystalline 2D perovskite crystals derived from FBTT and FBTP resemble those of their corresponding polycrystalline thin films as shown in FIGS. 10A-10C. These observations eliminate film quality and crystallinity as confounding factors governing the differential emission properties.

### Molecular Insights

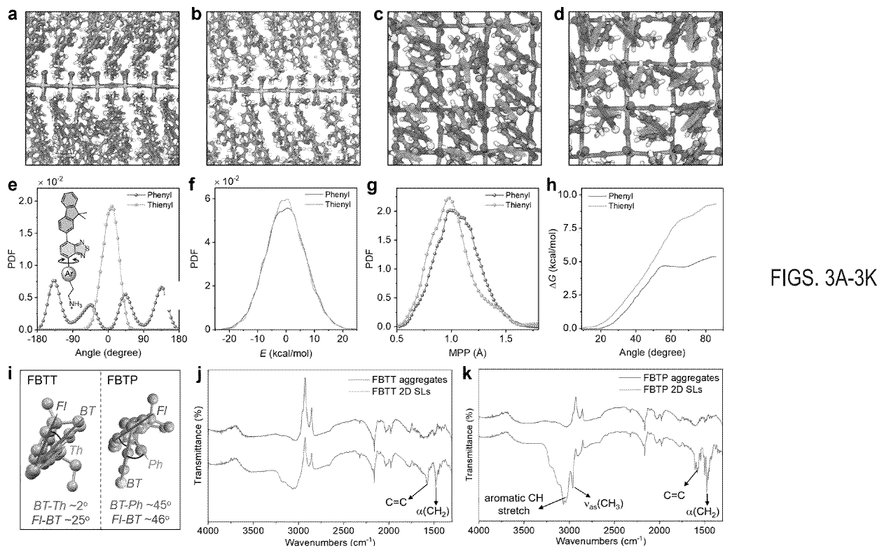

FIGS. 3A-3K show molecular insights into the rotational and vibrational behaviors of organic molecules confined in 2D SLs. FIGS. 3A, 3B show side view of thienyl- (FIG. 3A) and phenyl-based (FIG. 3B) 2D SLs during MD simulation. FIGS. 3C, 3D show top view of thienyl- (FIG. 3C) and phenyl-based (FIG. 3D) 2D SLs during MD simulation. Fluorene units are omitted for clarity; various lines denote benzothiadiazole. thienyl ring, and phenyl ring. FIG. 3E shows a probability distribution function (PDF) of each ligand's backbone dihedral torsion between benzothiadiazole and aromatic ring (Ar) within the perovskite lattice. FIG. 3F shows the energy PDF of each ligand within the perovskite lattice. FIG. ge shows a PDF of each ligand's molecular planarity parameter (MPP) within the perovskite lattice. FIG. 3H shows the free energy for neighboring ligand rotation within perovskite lattice. FIG. 3I shows a zoomed-in top view images of FBTT (left) and FBTP (right) molecules extracted from their corresponding 2D SL single-crystal structures; sulfur (S), nitrogen (N), carbon (C), hydrogen atoms are omitted for clarity; Th and Ph denotes thienyl and phenyl ring, respectively; BT denotes benzothiadiazole, and FI denotes fluorene unit. FIGS. 3J, 3K show FTIR of FBTT aggregates and 2D SLs films (FIG. 3J) and FBTP aggregates and 2D SL films (FIG. 3K), where the peak between 1450-1370 cm⁻¹ can be assigned to the bending mode of aliphatic CH₂ group (α(CH₂)) and the multipeak in 1620-1540 cm⁻¹ could come from the C═C stretching of aromatic linkers.

To understand the relationship between the emitter structures and their behaviors within the lattice, equilibrium molecular dynamics (MD) simulations were performed on individual FBTT-and FBTP-based layered perovskites, following equilibration and statistical sampling over finite-temperature equilibrium structures. As shown in FIGS. 3A, 3B, FBTT adopts a more ordered packing style than FBTP. Further investigations on each ligand's configuration reveal that FBTT ligands are more planar than FBTP, characterized by the fact that the benzothiadiazole and thienyl rings in FBTT ligand are parallel (FIG. 3C), while the benzothiadiazole and phenyl rings in FBTP are not (FIG. 3D). Co-planar molecules usually experience stronger intermolecular interactions, such as a-z stacking, that promote emission quenching and wavelength red-shifting, agreeing well with the experimental observations in FBTT.

To quantitatively understand the ligands'configuration and intermolecular interactions, the distribution of the inter-ring dihedral, the site energy (calculated as a sum over all intermolecular terms involving the ligand), and the molecular planarity parameter (MPP, calculated as the root-mean-square deviation of atoms from the fitting plane to the ligand) of each ligand were calculated. All distribution data are collected from each frame of the MD trajectory based on different ligands. The simulations on the dihedral between fluorene and benzothiadiazole give similar distribution profiles for both FBTT and FBTP, whereas the dihedral torsions between benzothiadiazole and phenyl/thienyl rings are significantly different. As shown in FIG. 3E, FBTT manifests a narrow dihedral distribution converging around 0 degrees, while FBTP's distribution spreads out peaked at about 45, 135 degrees, which is consistent with the DFT energy calculation for ligands'backbone dihedral torsion. The energy (FIG. 3F) and MPP (FIG. 3G) distributions show similar results, where FBTT has a narrower distribution, suggesting that FBTT is more planar and has a more ordered packing than FBTP (see the span of deviation from plane, SDP, below for more information). These match observations in the MD simulation in FIGS. 3C, 3D. To probe each ligand's packing behavior, a free energy analysis was conducted with respect to ligand rotation within the lattice (FIG. 3H). The reaction coordinate of the free energy is defined as the packing angle between the ligand being rotated and the reference ligand as shown in FIGS. 11A-11B. This shows that FBTT uses more energy than FBTP to break from parallel stacking (angle=0 degree). Additionally, the FBTP case has a plateau around 50 to 70 degrees, indicating that FBTP ligands are prone to reorganize themselves to a non-parallel packing pattern in the lattice (FIG. 3H). All the above analyses imply that FBTT is more planar and tends to have stronger intermolecular interactions, while FBTP is less planar and tends to behave like a single molecule within the lattice. These molecular scale differences reveal the subtle aspects of ligand design that conduce the formation of SMA upon designated lattice incorporation,

To experimentally examine the molecular configuration and packing behaviors of organic emitters in inorganic lattices, the single crystal structures were resolved. The single-crystal structures of FBTT-and FBTP-contained hybrid materials are also described later. The FBTT molecules in the perovskite lattice adopt a herringbone packing, which is a common motif for organic semiconductors as shown in FIGS. 12A-12B. The torsion angle between the benzothiadiazole and thienyl rings is about 2° (left, FIG. 31). In contrast, the packing motif of organic FBTP molecules in the perovskite lattice is dominated by two different stacking styles, crisscross and herringbone as shown in FIGS. 12A-12B. This stacking style is radically different from the normally observed herringbone or lamellar 2D π stacking in organic semiconductor crystals and organic molecule-incorporated 2D perovskite structures. Furthermore, the torsion angle between the benzothiadiazole and phenyl rings is found to be about 45° (right, FIG. 31). All the experimental outputs from single-crystal XRD results demonstrate that FBTT is more planar and has a more ordered packing than FBTP does, which is in agreement with MD simulation predictions.

Fourier-transform infrared spectroscopy (FTIR) was performed to inspect the footprint of molecular structures and intermolecular interactions. IR absorption from 3100-2900 cm⁻¹ was assigned to the C—H stretching mode (FIGS. 3J, 3K), In the FBTT case, the 2D SLs show a broad feature in this stretching region (FIG. 3J), which is identical to that of its aggregates. Clear fine structures from FBTP SLs in this stretching region (FIG. 3K), which are absent in the corresponding aggregates (FIG. 3K). The sharp peak at 2960 cm⁻¹ corresponds to the asymmetrical stretching of CH₃ groups that are attached to the fluorene unit, and the peaks around 3050 cm (FIG. 3K) seem to come from the C—H stretch of the aromatic ring in FBTP molecules. These sharp peaks and fine structures indicate that FBTP molecules possess sufficient freedom to vibrate like single molecules within the perovskite lattice.

### Chemical Tunability of SMA

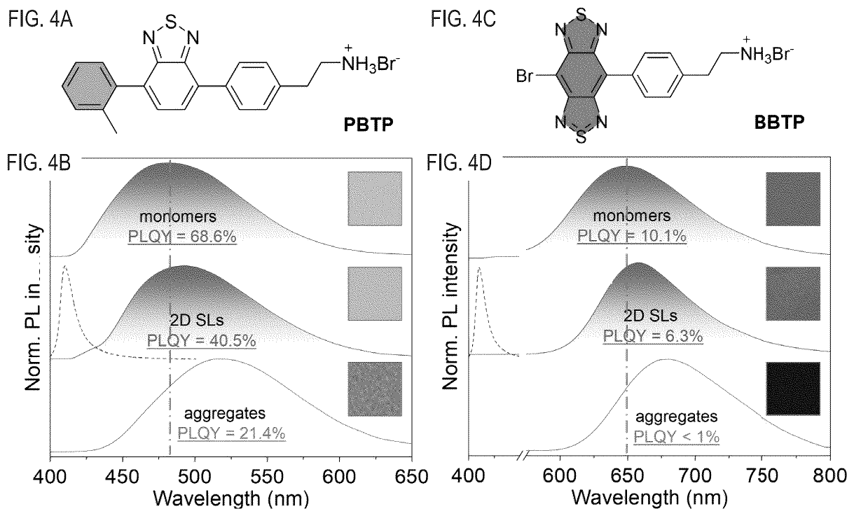

FIGS. 4A-4D show single-molecule behaviors of other organic emitters in 2D SLs. FIG. 4A shows a molecular structure of PBTP. FIG. 4B shows PL spectra and PLQY of PBTP monomer in PMMA film, PBTP 2D SLs, and PBTP aggregate films. FIG. 4C shows a molecular structure of BBTP. FIG. 4D shows PL spectra and PLQY of BBTP monomer in PMMA film, BBTP 2D SLs, and BBTP aggregate films. The inset in (FIG. 4B) and (FIG. 4D) are PL images of corresponding thin film samples, and all the image scales are 10 μm×10 μm.

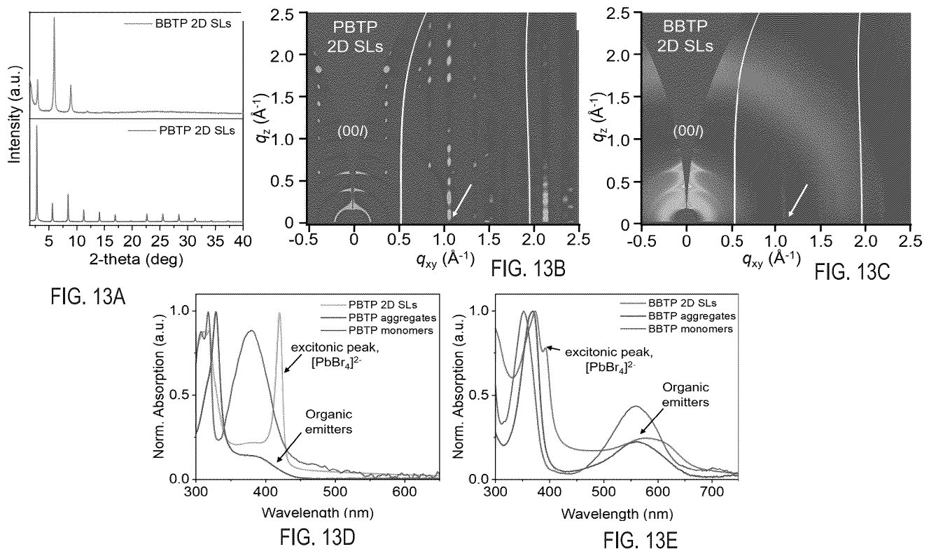

Two single-molecule-like emitters with different emission colors were developed. Specifically, replacing the fluorene unit with a weaker donor (tolyl group) generates a sky-blue emitter, PBTP (FIGS. 4A, 2-(4-(7-(o-tolyl)benzo[c][1,2,5]thiadiazol-4-yl)phenyl)ethan-1-ammonium bromide). And, substituting the benzothiadiazole group with a stronger acceptor (benzo[1,2-c:4,5-c′]bis([1,2,5]thiadiazole) produces a red emitter, BBTP (FIGS. 4C, 8-bromobenzo[1,2-c:4,5-c′]bis([1,2,5]thiadiazole-4-yl)phenyl)ethan-1-ammonium bromide). TDDFT calculations confirmed reversed type-I band alignment relative to [PbBr₄]²⁻ lattice as shown in FIGS. 6A-6C. In parallel, XRD, GIWAXS, and UV-vis measurements as shown in FIGS. 13A-12E indicate that organic emitters were successfully incorporated into the lead-bromide matrix. The PLQYs of 2D SLs are also much higher than that of the corresponding aggregates (FIG. 4B, FIG. 4D). Both PL emission wavelengths and PLQYs of 2D SLs are similar to that of the corresponding monomers and blue shifted from the aggregates, demonstrating the generality of the strategy. This is conceptually different from aggregation-induced emission (AIE), as AIE relies on the restriction of the intramolecular rotation of individual molecules, whereas the perovskite SLs herein keep the single molecular signature by regulating intermolecular distance at near equilibrium state. Additionally, the newly developed 2D SLs exhibit significantly improved photostability when compared with the well-known (PEA) PbBr4.

### Molecular Ensemble Properties

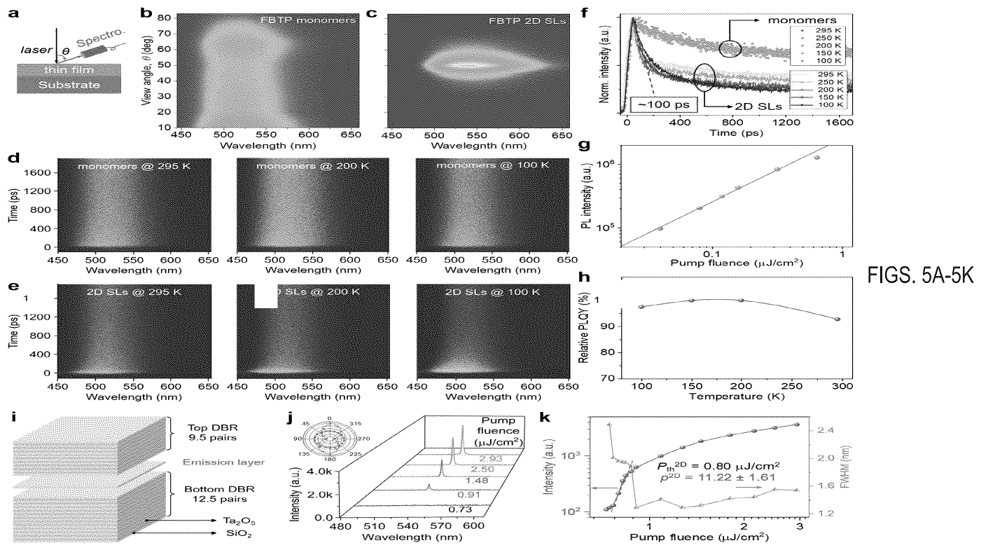

FIGS. 5A-5K show single-molecule-like aggregate behaviors of organic emitters in 2D SLs. FIG. 5A shows a scheme of the angle-dependent PL measurement set-up configuration. FIGS. 5B, 5C show angular resolved PL of FBTP monomers (FIG. 5B) and 2D SLs (FIG. 5C). Note, an s-polarized laser was used as the excitation source. FIGS. 5D, 5E show streak-camera measurement results on FBTP monomers (FIG. 5D) and 2D SLs (FIG. 5E) at different temperatures. FIG. 5F shows an extracted PL decay from steak-camera data shown in (FIG. 5D) and (FIG. 5E). The decay curves for the monomers all overlapped at different temperatures. FIG. 5G shows power-dependent PL intensity of FBTP 2D SLs at room temperature. FIG. 5H shows relative PLQY of FBTP SLs at different temperatures, using room-temperature PLQY as a reference. FIG. 5I shows a schematic structure of lasing device with emission layer (i.e., FBTP 2D SLs, monomers, and aggregates) sandwiched between two DBRs. FIG. 5J shows PL spectra evolution of FBTP 2D SL under different pump fluences. Inset is the polar plots of emission intensity at pump fluences below and above the threshold. FIG. 5K shows corresponding PL intensity against increasing pump fluences in log-log scale, showing a clear “kink” at a threshold energy density of Pₜₕ^{2D}=0.80 μJ/cm². The intensity dependence is fitted to a power law x^{D} with p^{2D}=11.22 above the threshold.

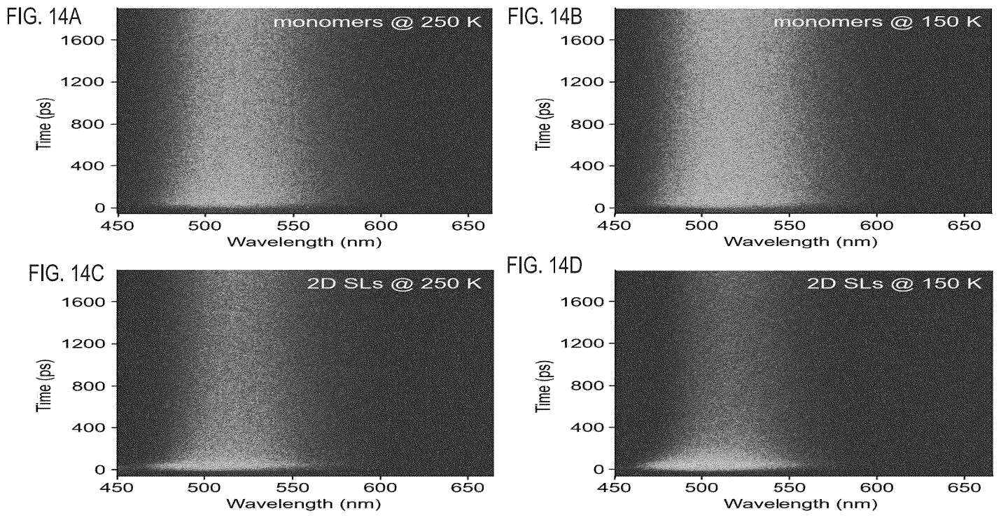

Owing to the ordered molecular arrangement in the SLs, we investigated the angle-dependent PL emissions of FBTP-based films (FIG. 5A), The angular PL of monomer and aggregate films exhibit a typical emission profile of isotropic emitters (FIG. 5B). The FBTP SL demonstrates a strong anisotropic feature, in which the directional emissions center around 50° (FIG. SC). This specific angle is perpendicular to the transition dipole of the organic emitters in the perovskite SLs. A short-lived PL component in the FBTP SLs film was observed, which is absent in FBTP monomers film that shows constant longer decay. To precisely resolve the timescale of the short lifetime component, temperature-dependent streak camera characterizations were conducted. Similarly, the FBTP monomers show consistent slow PL decay at different temperatures (FIGS. 5D, 5F and FIGS. 14A, 14B); whereas a short-lived component (below 100 ps) in FBTP SLs is clearly presented across wide temperature regions (FIGS. 5E, 5F and FIGS. 14C, 14D). Such an ultrafast decay has not been reported in a conventional organic single molecule system, which might be ascribed to the mutual interaction of the radiation field of those well-aligned neighboring single molecules, linking to the behaviors of ordered molecular ensembles or aggregates.

Note that all the temperature-dependent streak camera results were measured with a fluence of 0.1 μJ/cm², which is below the exciton-exciton annihilation regime (FIG. 5G), thus excluding the possibility of bimolecular-process-induced fast decay. Moreover, the relative PLQYs of 2D SLs at different temperatures are all over 90% and reach unity (100%) around 150-200 K (FIG. 5H). This implies that the nonradiative channels play an insignificant role in this ultrafast decay. There is a slight PLQY drop from 150 to 100 K, which can be ascribed to the inorganic sublattice contraction-induced emission quenching. This also indirectly indicates that the emitters are sustained as single molecules by the room-temperature perovskite lattice. Lastly, the PL spectra of short-lived components of FBTP 2D SLs were slightly blue shifted compared to the longer components (FIG. 5E). Based on the intramolecular charge transfer (ICT) nature of FBTP molecules, it may be that the short-wavelength emissions are coming from the locally excited (LE) states, which would be more feasible to undergo cooperatively radiative recombination.

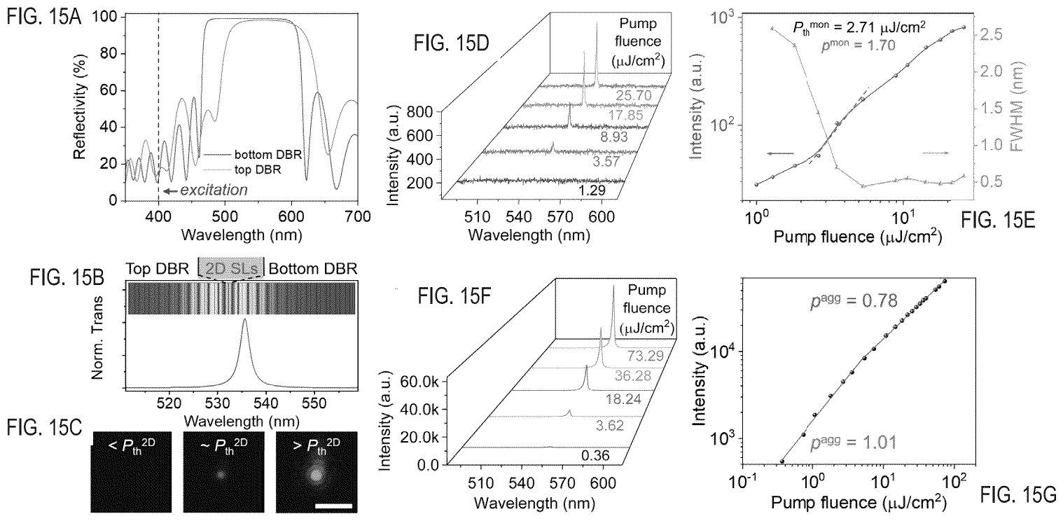

Lasing characterizations were conducted by placing the emission layer between two high-reflectivity distributed Bragg reflectors (DBRs, FIG. 5I). As the pump power increases, the emission intensity from FBTP 2D SL device steadily rises (FIG. 5J). When plotting the PL intensities against the pump fluences, a distinct “kink” emerges at a threshold Pₜₕ^{2D}=0.80 μJ/cm², which is accompanied by a sharp decline in emission linewidth (FIG. 5K), linearly polarized output (inset in FIG. 5J), and outstanding coherence, demonstrating the transition from spontaneous emission to full lasing oscillation. Furthermore, the superlinear intensity dependence is fitted to a power law y=x^{p} with p^{2D}=11.22 above the threshold for the 2D SL, which significantly exceeds that of the FBTP monomer (p^{mon}=1.70 with Pₜₕ^{mon}=2.71 μJ/cm² as shown in FIGS. 15A-15E). Lasing emission was not observed from the FBTP aggregates-based device, probably attributable to disorders and the ACQ effect as shown in FIGS. 15F-15G. These findings together validate that the exceptional gain performance of FBTP 2D SL resulted from the organized molecular arrangement at a near-equilibrium intermolecular distance.

A wide range of organic emitters have been successfully incorporated into the 2D perovskite lattice with tunable emissions spanning from blue to green and red. The molecular emitters with a suitable intramolecular twist in the perovskite SLs retain the characteristics of single molecules. These molecular emitters in perovskite SLs also exhibit dense packing and strong alignment resembling aggregates, which leads to unusual emission behaviors such as directional emission, enhanced radiative recombination rate, and low-threshold lasing. With a vast selection of organic emitters of desirable properties, the hybrid superlattice defines a rich family of optoelectronic materials for solid-state lighting applications. For instance, preliminary investigations on LED devices demonstrate over 50-fold enhancements in external quantum efficiency when the FBTP molecules are confined in the perovskite 2D SLs, compared to their true aggregates. The device structure for these LEDs includes a p-i-n configuration with the 2D SL as the emissive layer, as detailed in the supplementary information. The external quantum efficiency (EQE) and current efficiency were measured as a function of current density, and electroluminescence spectra confirmed the single-molecule-like emission characteristics. This may also be applicable to other inorganic motifs, such as layered metal halide-organic heterostructures, molecule-intercalated layered 2D atomic crystals SLs, and 1D or 0D organic-inorganic hybrid clusters. In brief, the SMA confined in perovskite 2D SLs go beyond the current classification of organic matter, such as typical H-, J-, or null-aggregates, representing a previously undiscovered phase at a near equilibrium distance.

### Methods

Chemicals and reagents. Organic solvents including anhydrous N,N-dimethylformide (DMF), chlorobenzene (CB), and dichloromethane (DCM), acetonitrile (ACN), o-dichlorobenzene (DCB), and solid chemicals including lead bromide (PbBr₂) were used. All chemicals and reagents were used as received from commercial suppliers without further purification, unless otherwise specified. The synthesis of organic molecular emitters (FBTT, FBTP, PBTP, BBTP) followed procedures including protection, coupling, deprotection, and purification steps. The organic cations should be soluble in common organic solvents such as DMF or DMSO at concentrations of at least about 2 mg/mL, and preferably up to about 10 mg/mL or higher, to enable homogeneous solution processing. The solubility may be adjusted by modifying the alkyl or aryl substituents on the cation. The organic emitters are synthesized using standard organic synthesis techniques, including protection, coupling, deprotection, and purification steps. The solubility of the organic cations in common organic solvents such as DMF or DMSO is one consideration for solution processing, with typical solubility requirements being several milligrams per milliliter. The precursor solutions for superlattice formation are prepared by dissolving the organic cation and metal halide in the chosen solvent at the desired stoichiometry.

Thin film fabrication. (1) The precursor solution for perovskites (2D SLs) was formulated with a concentration of 50 mM by dissolving organic emitters (i.e., FBTT, FBTP, PBTP, BBTP, PEA) and PbBr₂ in DMF with a stoichiometry ratio of 2:1 inside the nitrogen-filled glovebox. (2) The precursor solution for monomers was prepared by mixing 1 mg of organic emitters and 50 mg of PMMA with 1 mL mixed solvent (CB:DMF_{v/v}=1:1) and then stirring continuously at 100° C. overnight to obtain homogeneous polymer solutions. The weight percentage of organic emitters relative to PMMA is set at 2 wt % to ensure that organic emitters can be considered as isolated single molecules without experiencing obvious ACQ effect. (3) The precursor solution for aggregates was made by dissolving 10 mg of organic emitters in 1 mL DMF. All the solutions were then saved for further use. Bare Si/SiO₂ wafer, quartz, glass slides, or DBRs were cleaned by ultrasonication in detergent, de-ionized (DI) water, acetone, and isopropanol for 15 min each; then dried with dry air. (4) The substrates were treated with UV-Ozone for 20 min, and then transferred into a glove box for spin coating. The above precursor solutions were spin-coated onto the pre-cleaned substrates at 2000 rpm for 60 s, followed by thermal annealing on a hot plate at 150° C. for 10 min. These obtained films were used for further characterizations. Film thickness was measured by profilometry and confirmed to be in the range of 20-60 nm, depending on the organic emitter and processing conditions. Surface morphology was characterized by atomic force microscopy (AFM) and scanning electron microscopy (SEM), confirming uniform and continuous films.

The superlattice structure may be formed by spin-coating or drop-casting the precursor solution onto a substrate, followed by thermal annealing. The choice of solvent, concentration, spin speed, and annealing temperature are parameters for achieving uniform films and high crystallinity. Spin speeds from about 1000 to about 4000 rpm and annealing temperatures from about 50° C. to about 200° C. for about 5 to about 60 minutes have been found effective for different emitter and substrate combinations. The solubility of the organic cation in DMF or DMSO should be at least about 2 to about 10 mg/mL for homogeneous film formation. The process can be performed in ambient or inert atmosphere, but inert conditions (e.g., nitrogen glovebox) are preferred for maximum reproducibility and to minimize degradation of sensitive components. The precursor solution can be filtered (e.g., about 0.2 μm PTFE filter) prior to deposition to remove particulates and ensure film uniformity.

Alternative processing methods such as spray coating, vapor deposition, or chemical vapor transport may also be used, provided the solubility and volatility of the precursors are compatible. Post-deposition treatments, such as solvent vapor annealing or additional thermal annealing, can further improve film quality and crystallinity. The successful incorporation of the organic emitter into the inorganic lattice may be verified by X-ray diffraction, UV-vis absorption, and photoluminescence measurements. In some embodiments, the process may be performed in ambient atmosphere, provided the organic and inorganic precursors are sufficiently stable, although inert atmosphere processing may be preferred for reproducibility and material quality. The solubility of the organic cation in the chosen solvent may be at least several milligrams per milliliter to ensure homogeneous mixing and film formation. The temperature and duration of the annealing step can be varied (typically about 50 to about 200° C. for about 5 to about 60 minutes) to optimize crystallinity and phase purity. The method may be compatible with both small-scale laboratory fabrication and scalable manufacturing approaches, such as roll-to-roll coating or inkjet printing, provided the precursor rheology and drying kinetics are controlled.

The pitch of the inorganic sublattice can be tuned by varying the halide composition (e.g., substituting chloride or iodide for bromide) or by co-crystallization with different metal cations. For example, replacing bromide with chloride reduces the pitch to approximately 5.5 Å, while using iodide increases the pitch to approximately 7.5 to approximately 8 Å. This enables systematic adjustment of the intermolecular distance between organic emitters from about 5 Å to about 8 Å. This allows for precise control of the intermolecular distance between organic emitters, which in turn modulates the degree of electronic isolation and aggregate-like alignment. The degree of aggregation or isolation can also be influenced by the planarity and rotational freedom of the organic emitter, which is determined by the choice of linker and substituents. Patterning or spatial control of the superlattice structure may be achieved by selective deposition or by using patterned substrates.

The fabrication process may be scalable, and large-area films or bulk single crystals may be produced by adjusting the processing parameters. Reproducibility may be ensured by careful control of precursor concentrations, stoichiometry, and processing conditions. The main sources of defects or variability may be impurities in the precursors, fluctuations in processing temperature, and inconsistencies in solvent evaporation rates. These can be minimized by using high-purity reagents, precise temperature control, and optimized spin-coating or annealing protocols.

The pitch of the inorganic sublattice, and thus the intermolecular distance between organic emitters, can be tuned by varying the halide composition (e.g., using chloride, bromide, or iodide, or mixtures thereof) or by partial substitution of the metal cation (e.g., alloying lead with tin or other metals). This allows for systematic modulation of the degree of electronic isolation and aggregate-like alignment. The choice of organic emitter, including its backbone planarity and substituents, further enables control over the photophysical properties of the resulting superlattice. In some cases, co-crystallization of two or more different organic cations may be used to achieve multi-color emission or to tailor the packing and orientation of the emitters within the lattice.

Patterning or spatial control of the superlattice structure may be achieved by selective deposition, use of pre-patterned substrates, or photolithographic techniques. This enables the fabrication of pixelated or multi-segmented devices, such as display panels or multi-wavelength light sources. The superlattice films can be integrated with standard device architectures, including p-i-n diodes, vertical cavity surface-emitting lasers (VCSELs), and photodetector stacks. Electrical contacts may be deposited by thermal evaporation, sputtering, or solution processing, and encapsulation layers may be added to enhance environmental stability. The compatibility of the superlattice with flexible substrates and large-area processing enables the development of wearable or conformal optoelectronic devices.

Bulk single crystals of the superlattice can be grown by slow cooling, vapor diffusion, or anti-solvent crystallization methods. For example, a precursor solution containing the organic cation and metal halide can be allowed to slowly evaporate or be exposed to a non-solvent vapor, resulting in the nucleation and growth of large, high-quality crystals. These bulk crystals may be useful for fundamental studies of structure-property relationships and for applications requiring low optical loss or high coherence, such as microcavity lasers. In addition, nanocrystals or patterned microstructures can be fabricated by controlling the nucleation conditions, substrate surface energy, or by using template-assisted growth.

For device fabrication, the superlattice layer may be deposited directly onto a pre-patterned electrode or distributed Bragg reflector (DBR) stack, as required for light-emitting diodes or laser devices. The thickness of the superlattice layer can be adjusted to optimize optical confinement, charge injection, or outcoupling efficiency. In some embodiments, additional charge transport or blocking layers may be included to improve device performance. The process may be compatible with both rigid and flexible substrates, and the resulting devices can be encapsulated using standard thin-film encapsulation or lamination techniques to enhance operational lifetime.

The solubility of the organic cations in DMF or DMSO is typically at least about 2 mg/mL, and in some cases up to about 10 mg/mL or higher, which is sufficient for homogeneous mixing and film formation. The precursor solutions are generally filtered through a 0.2 μm PTFE filter prior to deposition to remove particulates and ensure film uniformity. The stoichiometry of organic cation to metal halide is typically maintained at about 2:1 for L₂MX₄ superlattice formation, but can be adjusted to optimize film quality or to accommodate different cation sizes.

Bulk single crystal growth. The FBTP-contained 2D SL single crystal weas obtained through a vapor diffusion method. Specifically, a 2:1 molar ratio of FBTP and PbBr₂ were dissolved in DMF to make a 25 mM solution by heating at 70° C. for 1 h. Then 0.1 mL of precursor solution was injected into a 4 mL small vial and placed in a 20 mL large vial containing 3 mL of a mixed solvent of CB and DCM with a volume ratio of 2:1, which was immediately sealed with a cap. The system was left undisturbed in a refrigerator (about 4° C.) for one month, yielding thin green plates. The FBTT-contained 2D SL single crystals were obtained through slow cooling crystallization using a solution composed of about 1 mg of FBTT, 20 mg of lead bromide (PbBr₂), 200 μL hydrobromide acid (HBr, 48 wt % in H₂O), and 300 μL of ethanol. Ethanol was added to assist the dissolution of the organic cations and crystallization. After mixing the precursors and solution, the contents of the sample vial were heated to over 100° C. by a heat gun until all the materials were completely dissolved and the solution was clear. The vials were then moved to a Dewar flask water bath at 95° C. to cool down for 72 hours until it reached room temperature. With this process, yellowish orange bulk single crystals were obtained in the form of thin plates.

Single-crystalline nanocrystal (NC) growth. 2D perovskite NCs were synthesized using a modified co-solvent evaporation method. 0.02 mmol of LBr (L=PEA, FBTT, FBTP) and 0.01 mmol of PbBr2 precursors were dissolved in a 2 mL solution of DMF and CB mixed in a 1:1 volume ratio to prepare 5 mM stock solutions. The concentrated PEA precursor solution was then diluted 120 times using a co-solvent system of CB, AN, and DCB mixed in a volume ratio of 2.5:1:0.01. For (FBTT)₂PbBr₄ and (FBTP)₂PbBr₄, the stock solution was diluted 720 times by CB/AN/DCB co-solvent with a volume ratio of 7.4:1:0.01. A Si/SiO₂ substrate was placed inside a 20 mL glass vial kept on a hot plate at 70° C. Approximately 10 μL of the diluted precursor was then dropped on the Si/SiO₂ substrate. The solvent evaporation is associated with the nucleation and growth of the nanocrystals on the substrate. The substrate was then removed from the hot plate in about 10 min, once all the solvent was evaporated.

DBR device fabrication. Three DBR devices were fabricated by sandwiching thin-film layers of FBTP 2D SLs, FBTP aggregates, FBTP monomers, respectively, between two highly reflective DBRs. The bottom DBR was first fabricated by an e-beam evaporator, consisting of 12.5 pairs of silicon dioxide (92.4 nm) and tantalum pentoxide (61.8 nm) capped by silicon dioxide. The emission layer was then spin-coated on the bottom DBR, where the thickness was adjusted to approximately 140 nm by controlling the spin speed or the concentration of precursor solutions. Finally, the bottom DBR with the emission layer on top was transferred into the e-beam evaporator chamber again to complete the fabrication of a top DBR, which consists of 9 pairs of silicon dioxide (91.8 nm) and tantalum pentoxide (65.6 nm).

The materials and method of incorporation are similar to those provided in U.S. Pat. No. 10,618,889 related to thiophene monoamine based organic-inorganic hybrid perovskites, and methods of making and using the perovskites, which is herein incorporated by reference in its entirety.

### Characterizations

Nuclear magnetic resonance (NMR) spectra. NMR spectra were acquired at room temperature using a 400-MHz spectrometer with CDCl₃ or DMSO-d₆ as the solvent and tetramethylsilane (TMS) as an internal standard. Chemical shifts of ¹H NMR and ^{13C}NMR signals were reported as values (ppm) relative to the TMS standard. High-resolution mass spectrometry (HR-MS) was performed in positive electrospray ionization (ESI) mode to confirm the molecular weights of the synthesized organic emitters. Single-crystal X-ray diffraction (XRD) was used to determine the crystal structures of the 2D SLs, with data deposited at the Cambridge Crystallographic Data Centre (CCDC numbers 2289715 and 2283333).

Mass spectra. High resolution mass spectrometry was acquired in positive Electrospray mode (ESI).

Single-crystal XRD analysis. Single crystals were analyzed using a diffractometer with kappa geometry, an I-μ-S microsource X-ray tube, a laterally graded multilayer Göbel mirror for single crystal monochromatization, and an area detector. Data collections were conducted at 150 K with Cu Kα radiation (λ=1.54178 Å).

UV-vis absorption spectra. Thin film absorption spectra were recorded on an UV-Vis-NIR spectrometer in transmission mode.

Photoluminescence (PL) spectra. Steady-state PL spectra were obtained with a microscope system integrated with a UV lamp. The filter cube contains a bandpass filter (330-385 nm) for excitation, a dichroic mirror (cutoff wavelength, 400 nm) for light splitting, and a 420 nm long-pass filter for emission collection. The collected PL signals were analyzed by a spectrometer.

Photoluminescence quantum yield (PLQY). The thin-film samples for PLQY measurements were deposited onto quartz substrates by following the preparation of precursor solutions and the fabrication procedures detailed in the “Thin film fabrication” subsection. The absolute PLQYs at room temperature were obtained by a three-step technique with a home-designed system, which consists of a continuous-wave laser (375 nm), an integrating sphere, optical fiber, and a spectrometer. The relative PLQYs at low temperatures were estimated based on the integrated emission intensity of the PL spectra at different temperatures for 2D SLs film. By taking the sample's PLQY at room temperature as a reference and correcting for absorption, the relative PLQYs of the film were then calculated.

Powder XRD. Thin film XRD was collected (Cu Ka, λ=1.54056 Å) in Bragg Brentano (BB) mode.

Thickness measurement. The thickness of the thin-film samples was measured with a profilometer. Here, the thickness of FBTT, FBTP, PBTP, BBTP, and PEA 2D SLs samples were determined to be 55.3, 58.2, 24.3, 23.1, and 20.8 nm, respectively.

Atomic force microscopy (AFM). The surface morphology and roughness were obtained with MultiMode 8-HR AFM in a tapping mode.

Scanning electron microscopy (SEM). Thin film SEM images were acquired with a high-resolution field emission SEM.

Fluorescence lifetime imaging microscopy (FLIM). Fluorescence lifetime imaging microscopy (FLIM) measurements were performed using a confocal microscope with water immersion objective (60×, N.A.=1.2) equipped with ISS. Specifically, samples were excited using a 440 nm pulsed laser with modulation frequency of 10 MHz and imaged through 506 nm long pass filter followed by MPD APD detectors. After image collection, biexponential fitting of FLIM images was performed using software (ISS) to obtain fluorescent lifetimes of each pixel.

Grazing incidence wide angle X-ray scattering (GIWAXS). GIWAXS spectra were collected at beamline 7.3.3. utilizing an incident angle of 0.18° and wavelength of 1.24 angstrom (energy 10 keV). The data were calibrated using silver behenate as a standard.

Fourier transform infrared (FTIR) spectroscopy. Attenuated total reflectance (ATR)-FTIR spectroscopy was conducted on a FTIR, equipped with diamond ATR crystal sampling accessory, with N₂ purging.

Low temperature PL and time-resolved PL (TRPL) measurements. A confocal micro-PL set-up was used to carry out temperature dependent steady-state and time-resolved optical measurements. A 447 nm picosecond pulsed diode laser was used as the excitation source and focused onto the surface of the samples using an objective (40×, N.A.=0.6). The emitted signal was collected by the same objective, dispersed with a monochromator, and detected by a spectrometer and CCD. The excitation scatter was rejected using a suitable optical filter placed before the detector. For the time-resolved PL dynamics, the signal was detected by a single photon avalanche diode with a single photon counting module, with a time resolution of about 100 ps. For most of the measurements, a low excitation fluence of 0.1 μJ/cm² was used to prevent the onset of parasitic bimolecular processes such exciton-exciton annihilation.

For the temperature-dependent PL measurements, a closed-cycle optical cryostat was used. The sample was placed on the holder, and a hard vacuum was established in the sample chamber. Temperatures in the range of 100-295 K, with a temperature stability<10 mK, were then attainable using the control units.

Angle-dependent PL measurements. Angular resolved PL measurements were performed. The sample is illuminated with a pulsed laser (100 fs, 400 nm) produced by the second harmonic generation from a Ti: Sapphire laser system. The laser pulse polarization is controlled by a polarizer and half-wave plate and impinges on the sample at normal incidence. The excited photoluminescence light is collected by a lens coupled to an optical fiber and finally directed into a spectrometer. The angle subtended by the lens is approximately 1 degree.

Temperature-dependent streak camera measurements. The samples were excited with a 440 nm wavelength light pulses from an optical parametric amplifier powered by an amplifier with a 2 kHz repetition rate and 170 fs pulse duration. The beam was focused with a lens into a 1 mm spot size on the sample that was mounted in a cryostat and held under a vacuum of <8×10⁻⁵ mbar. The PL was collected by an achromatic lens and guided into a spectrograph, which was connected to a charge-coupled device camera and streak camera for performing time-integrated PL and time-resolved PL measurements, respectively.

Photo-stability test. The photo-stability test on the 2D perovskite thin-film samples were carried out by tracking their absorption spectra under the irradiation of a UV curing lamp in glovebox, where the UV lamp had an output power of 0.31 W/cm² and was 5-cm away from the samples.

Lasing characterizations. Optically-pumped lasing measurements were carried out on a far-field micro-PL system in ambient condition. The excitation pulses (400 nm, about 100 fs, 1 kHz) were generated from the second harmonic of the fundamental output of a regenerative amplifier (800 nm, about 100 fs, 1 kHz), which was in tum seeded by a mode-locked Ti:sapphire laser (800 nm, ˜100 fs, 80 MHz). The DBR devices with emission layer sandwiched between two DBRs were locally excited with a laser beam focused down to about 50 μm in diameter through an objective (5×, N.A.=0.15), with input power altered by neutral density filters. After passing through a 420 nm long-pass emission filter, the collected PL signal from the DBR devices was subsequently coupled to a grating spectrometer and recorded with a thermoelectrically cooled CCD. The lasing threshold was determined by plotting the emission intensity as a function of pump fluence and identifying the characteristic “kink” in the log-log plot. The power factor above threshold was extracted by fitting the intensity dependence to a power law. Polarization and coherence properties of the lasing emission were further characterized using polarization-resolved measurements and a Michelson interferometer setup, respectively.

Coherence measurements. The spatial coherence of the lasing emission from the DRB device was evaluated by a Michelson interferometer setup. Initially, the emission from the DBR device was divided into two beams with a beamsplitter, which were subsequently directed to two separate arms of the interferometer. These beams were then reflected by the interferometer mirrors and overlapped on a CCD camera. The length of one interferometer arm was precisely adjusted to ensure that both beams travelled the same distance before reaching the CCD camera. Clear interference fringes will be recorded if the initial emission exhibits coherence.

### Simulations

Molecular dynamics (MD) simulations. Unbiased MD sampling: The modified MYP model was used for all simulations as described in our previous work. LAMMPS and PLUMED were used to perform the MD simulations. All simulations used 1 fs integration timestep and periodic boundary conditions (PBC). Long-range electrostatics were modeled using the particle-particle-particle-mesh (PPPM) algorithm and Lennard-Jones interactions were truncated at 15 Å. The initial structure of 2D perovskites were generated by constructing representative unit cells of ideal perovskites lattice with the bulky organic cations placed at the surface. The simulation was first relaxed in the NVE ensemble with restrained atomic displacements of 0.01 Å per timestep for 50 ps, followed by a 100 ps NPT equilibration with a thermostat and barostat. The boundary of y-direction, which is parallel to the bulky organic cations, is extended by 20 Å to prevent the interaction of organic cations from different sides due to PBC. During the NPT equilibration, the barostat was only applied to x and z-direction, which are normal to the bulky organic cations. Finally, 100 ps NPT simulation is conducted to evaluate the distribution of backbone dihedrals, the site energy of ligands, and MPP.

Free energy calculation on the ligand rotation: The reaction coordinate of the free energy calculation is defined as the angle between the fitted planes of two randomly picked neighboring ligands. Steered molecular dynamics (SMD) were then used to calculate the free energy curve. In SMD, we use a spring constant of 1000 kcal (mol-Å)⁻¹ and a constant velocity of 0.0125 rad/ps to steer the ligand into the target packing angle. All the reported results are calculated based on five independent simulation runs.

DFT calculations. Geometry optimizations and excited state calculations for FBTT, FBTP, PBTP, and BBTP molecules were carried out by means of density function theory (DFT) and time-dependent DFT (TDDFT) as implemented in the Gaussian 16 package using the B3L YP functional and def2-TZVP basis set in vacuum. The alkylammonium tail is not included for brevity, which tends to be flexible and varies its geometry depending on the matrix. Based on our experience, expensive basis set like def2-TZVP is used to achieve adequate accuracy in TDDFT calculations when considering the band alignment within perovskites. Transition dipole moments were visualized with the multiwfn software.

Optical field distribution simulation. The electric field intensity distribution in the 2D SLs-based DBR device was calculated in the electromagnetic wave frequency domain by using software. A periodic boundary condition was applied to the modelling configuration. The transmitted spectrum was retrieved by setting the bottom side of 2D SLs layer as a periodic excitation port.

FIGS. 6A-6C show DFT and TDDFT simulations on the energy level of molecular emitters. FIG. 6A shows molecular structures of four different organic emitters. FIG. 6B shows the calculated HOMO-LUMO and SI level of organic molecules relative to the valance band maximum (VBM)-conduction band minimum (CBM) of lead-bromide matrix. The VBM-CBM value of [PbBr₄]²⁻ was adapted from literature. FIG. 6C shows the scheme of the band alignment in organic-inorganic perovskite 2D SL structures including type-I, type-II, and reversed type-I.

FIGS. 7A-7B show the extracted azimuthal distribution of GIWAXS intensity for 2D perovskites at a typical q near 0.5 A⁻¹ (dashed rings in FIGS. 2B and 2F). FIG. 7A shows FBTT 2D SLs. FIG. 7B shows FBTP 2D SLs. Zero and 180 degrees correspond to q_{xy} plane (vertical orientation), and 90 degrees correspond to q_{z} direction (horizontal orientation).

The FBTT sample shows a peak scattering intensity of about 2200 at 90 degrees, which is very similar to that of FBTP (about 2100). At 0 or 180 degrees, FBTT shows substantial scattering with an intensity of about 410, while FBTP has a negligible scattering. Here, the orientation factor was defined as the scattering intensity ratio between 0 (180) degrees and 90 degrees, which yields a value of 0.19 and about 0 for FBTT and FBTP, respectively. A greater orientation factor value suggests a preferred orientation along the q_{xy} direction, which corresponds to a vertically oriented [PbX₄]²⁻ inorganic sublattice relative to the substrate. Therefore, the FBTT sample is dominated by horizontal orientation with small fraction of vertical orientation, while the FBTP sample exhibits an almost perfectly horizontal orientation.

FIGS. 8A-8C show FBTP emitters confined in 2D SLs with tunable inorganic sublattices. FIG. 8A shows PL spectra; FIG. 8B shows UV-vis spectra; and FIG. 8C shows XRD of FBTP-contained 2D SLs with different halide compositions.

FIGS. 9A-9D show the AFM surface morphology study on both molecular aggregates and 2D perovskites thin-film samples. FIG. 9A shows FBTT; FIG. 9B shows FBTP; FIG. 9C shows PBTP; FIG. 9D shows BBTP. The areas of all images are 4 μm×4 μm.

FIGS. 10A-10C show 2D perovskite nanocrystals and their corresponding PL spectra. FIG. 10A shows (PEA)₂PbBr₄ NC; FIG. 10B shows (FBTT)₂PbBr₄ NC; FIG. 10C shows (FBTP)₂PbBr₄ NC. The scale bars are 5 μm.

The PEA sample shows a square shape with violet emission from the [PbBr₄]²⁻ inorganic sublattice, which is consistent with the results from the literature, demonstrating the successful growth of single-crystalline (PEA)₂PbBr₄ 2D perovskite. By replacing the PEA with FBTT or FBTP, rectangular nanocrystals were obtained employing a similar crystal growth procedure, implying the formation of single-crystalline FBTT-and FBTP-based 2D perovskite nanocrystals. Moreover, FBTT-and FBTP-based nanocrystals exhibit strong orange and green emission, respectively, which is likely from the organic molecules. By taking a closer look at their PL spectra, the PL peak of the (FBTT)₂PbBr₄ nanocrystal is closer to that of FBTT aggregates, while the PL peak of the (FBTP)₂PbBr₄ nanocrystal closely resembles that of FBTP monomer. These findings align well with observations from thin-film samples, thus ruling out the influence of crystallinity on different emission properties.

FIGS. 11A-11B show a schematic illustration of MD simulations on organic molecules rotation within perovskite lattice. FIG. 11A shows FBTT-contained 2D SLs. FIG. 11B shows FBTP-contained 2D SLs. The dash-lined frames highlight the molecules under rotation investigation.

FIGS. 12A-12B show the packing styles of organic molecules within 2D SLs. FIG. 12A shows a view down the long molecular axis of FBTT molecules in the SLs, which clearly demonstrates a traditional herringbone packing style. FIG. 12B shows a view down the long molecular axis of partial FBTP molecules in the SLs, revealing a novel molecular packing style. H atoms and inorganic sublattices are omitted for clarity.

FIGS. 13A-13B show the structural characterizations and UV-vis spectra of PBTP and BBTP-based thin films. FIG. 13A shows XRD and FIGS. 13B-13C show GIWAXS patterns for perovskite thin films incorporated with PBTP (b) and BBTP (c) molecules. XRD and out-of-plane (q_{z}) GIWAXS patterns help verify that both PBTP and BBTP have been successfully incorporated into the lead-bromide matrix, forming a layered structure. The in-plane spacing is determined to be 5.98 and 5.76 Å from the q_{xy} at 1.05 and 1.09 Å⁻¹ for PBTP and BBTP (similar to the 3D perovskite lattice), respectively, which indicates the 2D structures of these organic emitters incorporated 2D SLs. FIG. 13D shows UV-vis spectra of PBTP doped PMMA (monomers), neat PBTP aggregates, and PBTP 2D SLs films. FIG. 13E shows UV-vis spectra of BBTP doped PMMA (monomers), neat BBTP aggregates, and BBTP 2D SLs films. The sharp UV-vis peak around 400 nm and the nearby shoulder peak from 2D SLs films can be indexed to the excitonic peak of perovskites and organic emitters, respectively, further supporting the formation of 2D perovskite SLs.

FIGS. 14A-14D show streak camera results at different temperatures. FIGS. 14A-14B show FBTP monomers at 250 K (FIGS. 13A) and 150 K (FIG. 13B). FIGS. 14C-14D show FBTP 2D SLs at 250 K (FIGS. 13C) and 150 K (FIG. 13D).

An examination of the FBTP SL sample and its spectroscopic features, several reasons rule out the dispersive energy transfer explanation. (1) The organic emitters in the perovskite lattice are the identical molecules, typically exhibiting homogeneous energy distribution. This is different from the conjugated polymer cases, which shows dispersive energy transfer from high-energy site to low-energy site due to the inhomogeneously broadened density of states with different effective conjugation length. (2) Forster-type energy transfer usually requires effective spectral overlap between the absorption and emission spectra. The spectral overlap is minimal in our 2D SL system (FIGS. 2G and 10C), which may render the dispersive energy transport less effective. Additionally, the excitation wavelengths used for TRPL and streak camera measurements are 447 and 440 nm, respectively, which are near the tail end of the absorption band. This suggests that the dispersive energy transfer is unlikely to play a significant role in the observed bathochromic shift over time. (3) If the dispersive energy transport were occurring in FBTP 2D SLs, the PL spectra would be expected to continuously red-shift and reach a stationary energy in a nanosecond timescale. In contrast, our streak camera results (FIG. 5E and FIGS. 14C-14D) show red-shifting only within about one hundred picoseconds. More importantly, the final emission state reached in FBTP SL is exactly the same as that of the FBTP monomer (FIG. 5D and FIGS. 14A-14B), This behavior implies that the emerging rapid decay at short-wavelength side originates from the high-energy emission state (i.e., LE state), rather than from the high-energy fraction of the emitters (broadened density of states).

FIGS. 15A-15G show lasing characterization on FBTP monomer and FBTP aggregates. FIG. 15A shows experimentally measured reflectance spectra for DBRs, where the pump laser was directed into the device from top DBR to excite the sample, followed by the collection of emission from the same side. The wavelength range of top DBR with high reflectance (>98%) fully covers the optical gain region of FBTP monomer, 2D SLs, and aggregates. FIG. 15B shows simulated transmittance spectra of a 2D SLs-based DBR device, which matches well with the lasing spectra from this device. Inset: electric field distribution of the 536 nm optical standing wave inside the device. FIG. 15C shows PL images of a 2D SLs-based DBR device with pump fluence below, near, and above the threshold. Scale bar: 100 μm. FIG. 15D shows PL spectra evolution of FBTP monomer under different pump fluences. FIG. 15E shows corresponding PL intensity against increasing pump fluences in log-log scale, showing a clear “kink” at a threshold energy density of 2.71 μJ/cm². The superlinear intensity dependence is fitted to a power law x^{p} with p^{mon}=1.70 above the threshold. FIG. 15F shows PL spectra evolution of FBTP aggregates under different pump fluences. FIG. 15G shows corresponding PL intensity against increasing pump fluences in log-log scale, which reveals linear (p^{agg}=1.01) and sublinear (p^{agg}=0.78) growth across a broad pump fluence range, suggesting the absence of lasing from FBTP aggregates.

### Devices

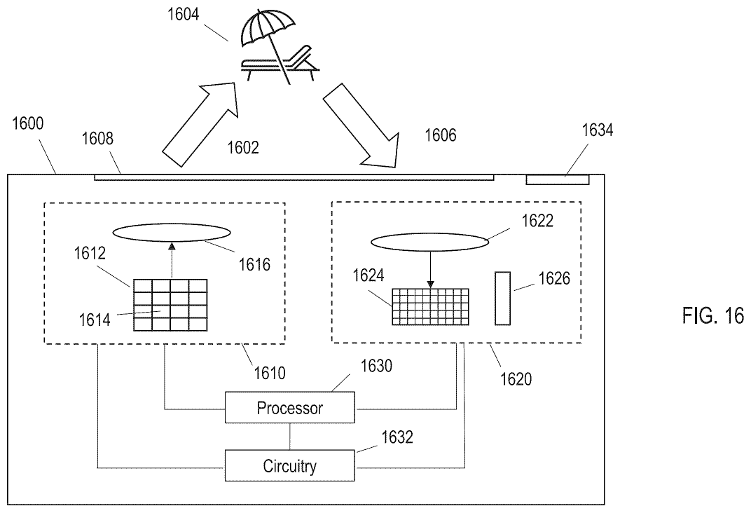

FIG. 16 shows a device, in accordance with some examples. The device 1600 may be, for example, a smart phone or standalone camera that contains a light source 1610 such as the light emitters described herein. The device 1600 may also include a camera 1620 that captures an image of a scene 1604 during an exposure duration of the camera 1620, whether or not the scene 1604 is illuminated by the light source 1610. A processor 1630 may be used to control various functions of the device 1600, including activation of the light source 1610 and the camera 1620 in addition to whether or not a shutter, disposed in an opening 1608 of a housing of the device 1600, is open.

The opening 1608 may be a single opening as shown in FIG. 16 or may include multiple separate openings. Similarly, the shutter may be a single shutter that covers both the light source 1610 and the camera 1620 or may include multiple separate shutters that covers only one of the light source 1610 or the camera 1620 and are individually controllable by the processor 1630.

The light source 1610 may include one or more LED arrays 1612 on a backplane such as a complementary metal oxide semiconductor (CMOS) or silicon (Si) backplane, for example. Each of the one or more LED arrays 1612 may include multiple LEDs 1614 that may produce visible and/or infrared light during at least a portion of the exposure duration of the camera 1620. At least some of the LEDs 1614 may be NIR light emitters for example.

Each LED 1614 or set of LEDs 1614 may form a pixel of the corresponding LED array 1612. LEDs 1614 may emit visible light (e.g., red, green, blue) or NIR light, as above. LEDs 1614 in a particular LED array 1612 that emit light in the infrared spectrum may be, for example, interspersed with LEDs 1614 that emit light in the visible spectrum, or each type of LED (visible emitter/infrared emitter) may be disposed on different sections of the particular LED array 1612. Alternatively, each LED array 1612 may only emit light in either the visible spectrum or the infrared spectrum; separate (one or more) LED arrays may be used to emit light in the infrared spectrum. Each of the individual LED arrays 1612, LEDs 1614 within each LED array 1612, and/or groups of LEDs 1614 within each LED array 1614 (e.g., sets of 3×3 LEDs) may be individually controllable by the processor 1630.

The light source 1610 may include at least one lens 1616 and/or other optical elements such as reflectors. The lens 1616 and/or other optical elements may direct the light emitted by the one or more LED arrays 1612 toward the scene 1604 as illumination 1602. In some embodiments, reflectors may be disposed between adjacent pixels in the LED array 1612 or at the edges of the LED array 1612 to increase the light-extraction efficiency and provide beam shaping.

The camera 1620 may sense light at at least the wavelength or wavelengths emitted by the one or more LED arrays 1612. Similar to the light source 1610, the camera 1620 may include optics (e.g., at least one camera lens 1622) that are able to collect reflected light 1606 of the illumination 1602 that is reflected from and/or emitted by the scene 1604. The camera lens 1622 may direct the reflected light 1606 onto a light sensor 1624 to form an image of the scene 1604 on the light sensor 1624. The light sensor 1624 may contain multiple pixels to have a desired resolution (e.g., each pixel may correspond to a different LED 1614). In some embodiments, the light sensor 1624 may also be disposed on the CMOS or Si backplane.

The processor 1630 may control and drive the LEDs 1614 in the one or more LED arrays 1612 via circuitry 1632 that includes one or more drivers. For example, the processor 1630 may optionally control one or more LEDs 1614 in the one or more LED arrays 1612 independent of another one or more LEDs 1614 in the one or more LED arrays 1612, so as to illuminate the scene in a specified manner. The processor 1630 may also receive a data signal that represents the image of the scene 1604 and process the signal to adjust driving of the LEDs 1614 or otherwise adjust the image as desired.

In addition, one or more detectors 1626 may be incorporated in the camera 1620. In other embodiments, instead of being incorporated in the camera 1620, the one or more detectors 1626 may be incorporated in one or more different areas, such as the light source 1610 or elsewhere close to the camera 1620. The one or more detectors 1626 may include multiple different sensors to sense visible and/or infrared light (e.g., from the scene 1604), ambient light and/or variations/flicker in the ambient light in addition to reception of the reflected light from the LEDs 1614, or other actions, such as physical movement of the device 1600.

The light sensor 1624 of the camera 1620 may be of higher resolution than the sensors of the one or more detectors 1626 to obtain an image of the scene with a desired resolution. The sensors of the one or more detectors 1626 may have one or more segments (that are able to sense the same wavelength/range of wavelengths or different wavelength/range of wavelengths), similar to the LED arrays 1612. In some embodiments, if multiple detectors are used, one or more of the detectors may detect visible wavelengths and one or more of the detectors may detect infrared wavelengths; like the one or more LED arrays 1612, the one or more detectors 1626 may be individually controllable by the processor 1630.

In some embodiments, instead of, or in addition to, being provided in the camera 1620, one or more of the sensors of the one or more detectors 1626 may be provided in the light source 1610. In some embodiments, the light source 1610 and the camera 1620 may be integrated in a single module, while in other embodiments, the light source 1610 and the camera 1620 may be separate modules that are disposed on a PCB. In other embodiments, the light source 1610 and the camera 1620 may be attached to different PCBs—for example, as the camera 1620 may be thicker than the light source 1610, which may result in design issues if the light source 1610 and the camera 1620 are attached to the same PCB. In the latter embodiment, multiple openings may be present in the housing at least one of which may be eliminated with the use of an integrated light source 1610 and camera 1620.

The LEDs 1614 may be driven using a direct current (DC) driver or pulse width modulation (PWM) in the circuitry 1632. The LEDs 1614 may be driven using a PWM whose phase shift varies between LEDs 1614 to reduce potential current surge issues. As shown, the circuitry 1632 may include one or more drivers used to drive the LEDs 1614 in the one or more LED arrays 1612.

The device 1600 may also include an input device 1634, for example, a user-activated input device such as a button that is depressed to take a picture. The light source 1610 and camera 1620 may be disposed in a single housing.

As above, the light source 1610 of FIG. 16 may contain individually addressable LED segments to allow selective illumination of the scene 1604. For array sizes larger than 3×3 matrices, the LED segments may be combined with an integrated driver to allow the function of individual addressability and obtain the small form factor desired for mobile devices without creating issues in layout of the semiconductor layers used to create the integrated devices. LEDs can be used in the device 1600 shown in FIG. 16 to form different types of displays (e.g., smart phone displays, computer displays, smart watches, monitors, and TVs) and light engines including adaptive automotive headlights, AR, VR, or mixed-reality (MR) headsets, smart glasses, et al. The individual LED pixels in these architectures may have an area of few square millimeters down to few square micrometers depending on the matrix or display size and pixel-per-inch requirements.

The superlattice materials can be integrated into a variety of device architectures, including but not limited to light-emitting diodes, lasers, photodetectors, and solar cells. Device structures include p-i-n configurations for LEDs and vertical cavity structures for lasers. Electrical contacts and encapsulation layers may be added as needed for device operation and stability. The unique combination of single-molecule-like emission and aggregate-like alignment in the superlattice enables devices with high external quantum efficiency, low lasing threshold, and robust operational stability. For example, light-emitting diodes incorporating the superlattice as the emissive layer have demonstrated external quantum efficiencies (EQE) exceeding 2.5%, and in some cases, more than 50 times higher than devices using the same emitter in an aggregate state. Optically pumped lasers based on the superlattice structure have shown lasing thresholds as low as 0.8 μJ/cm² and power factors above 10. In some embodiments, the superlattice layer may be deposited by solution processing (e.g., spin-coating, spray-coating) directly onto device substrates, and is compatible with integration onto distributed Bragg reflectors (DBRs) for laser devices or onto transparent electrodes for LEDs. The superlattice structure does not significantly complicate device fabrication and may be compatible with both rigid and flexible substrates.

The superlattice structure may not significantly complicate device fabrication and may be compatible with standard thin-film processing techniques. In some embodiments, the superlattice layer may be deposited by solution processing, vapor deposition, or printing directly onto device substrates, including flexible or patterned substrates. The process is compatible with integration onto CMOS backplanes, transparent electrodes, or distributed Bragg reflectors. For laser devices, the superlattice may be sandwiched between high-reflectivity mirrors to form a vertical cavity, and the emission properties can be tuned by adjusting the layer thickness and cavity design. For LEDs, additional charge transport and injection layers may be included to optimize carrier balance and efficiency. The superlattice materials may also be used in photodetectors or solar cells, where the unique photophysical properties can enhance sensitivity or spectral selectivity.

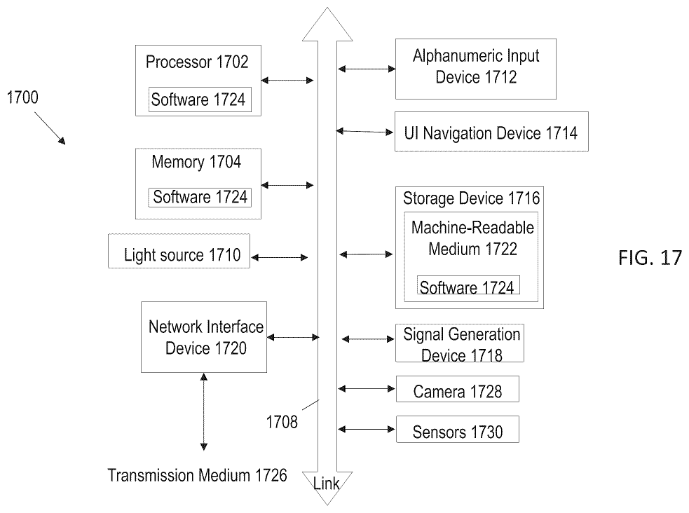

FIG. 17 illustrates an example of an electronic device in accordance with some embodiments. The electronic device 1700 may be, for example, a display, a monitor or screen, a wearable/mobile display device such as an AR/VR headset, a vehicular headlight, lighting for a particular area, or any other lighting arrangement. Various elements may be provided on a backplane indicated above, while other elements may be local or remote. Examples, as described herein, may include, or may operate on, logic or a number of components, modules, or mechanisms.

Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The electronic device 1700 may include a hardware processor (or equivalently processing circuitry) 1702 (e.g., a central processing unit (CPU), a GPU, a hardware processor core, or any combination thereof), a memory 1704 (which may include main and static memory), some or all of which may communicate with each other via an interlink (e.g., bus) 1708. The memory 1704 may contain any or all of removable storage and non-removable storage, volatile memory or non-volatile memory. The electronic device 1700 may further include a light source 1710 such as the light emitters described herein, or a video display, an alphanumeric input device 1712 (e.g., a keyboard), and a user interface (UD) navigation device 1714 (e.g., a mouse). In an example, the light source 1710, input device 1712 and UI navigation device 1714 may be a touch screen display. The electronic device 1700 may additionally include a storage device (e.g., drive unit) 1716, a signal generation device 1718 (e.g., a speaker), a network interface device 1720, one or more cameras 1728, and one or more sensors 1730, such as a global positioning system (GPS) sensor, compass, accelerometer, or other sensor such as those described herein. The electronic device 1700 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). Some of the elements, such as one or more of the sparse arrays that provide the light source 1710 may be remote from other elements and may be controlled by the hardware processor 1702.

The storage device 1726 may include a non-transitory machine readable medium 1722 (hereinafter simply referred to as machine readable medium) on which is stored one or more sets of data structures or instructions 1724 (e.g., software) embodying or utilized by any one or more of the techniques or functions described herein. A storage device 1726 that includes the non-transitory machine-readable medium should not be construed as that either the device or the machine-readable medium is itself incapable of having physical movement. The instructions 1724 may also reside, completely or at least partially, within the memory 1704 and/or within the hardware processor 1702 during execution thereof by the electronic device 1700. While the machine readable medium 1722 is illustrated as a single medium, the term “machine readable medium” may include a single medium or multiple media (e.g., a centralized or distributed database, and/or associated caches and servers) configured to store the one or more instructions 1724.

The term “machine readable medium” may include any medium that is capable of storing, encoding, or carrying instructions for execution by the electronic device 1700 and that cause the electronic device 1700 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 1724 may further be transmitted or received over a communications network using a transmission medium 1716 via the network interface device 1720 utilizing any one of a number of wireless local area network (WLAN) transfer protocols or a SPI or CAN bus. Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as Institute of Electrical and Electronics Engineers (IEEE) 1702.11 family of standards known as Wi-Fi, IEEE 1702.14 family of standards known as WiMax, IEEE 1702.14.4 family of standards, a Long Term Evolution (LTE) family of standards, a Universal Mobile Telecommunications System (UMTS) family of standards, peer-to-peer (P2P) networks, a next generation (NG)/6^{th} generation (6G) standards among others. In an example, the network interface device 1720 may include one or more physical jacks (e.g., Ethernet, coaxial, or phone jacks) or one or more antennas to connect to the transmission medium 1716,

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical CPU, a single-or multi-core processor, and/or any other device capable of executing or otherwise operating computer-executable instructions, such as program code, software modules, and/or functional processes.

The camera 1728 may sense light at least the wavelength or wavelengths emitted by the LEDs. The camera 1728 may include optical elements (e.g., at least one camera lens) that are able to collect reflected light of illumination that is reflected from and/or emitted by an illuminated region. The camera lens may direct the reflected light onto a multi-pixel sensor (also referred to as a light sensor) to form an image of on the multi-pixel sensor.

The processor 1702 may control and drive the LEDs via one or more drivers. For example, the processor 1702 may optionally control one or more LEDs in LED arrays independent of another one or more LEDs in the LED arrays, so as to illuminate an area in a specified manner.

In addition, the sensors 1730 may be incorporated in the camera 1728 and/or the light source 1710. The sensors 1730 may sense visible and/or infrared light or movement (e.g., via a gyroscope) among others. The sensors may have one or more segments (that are able to sense the same wavelength/range of wavelengths or different wavelength/range of wavelengths), similar to the LED arrays.

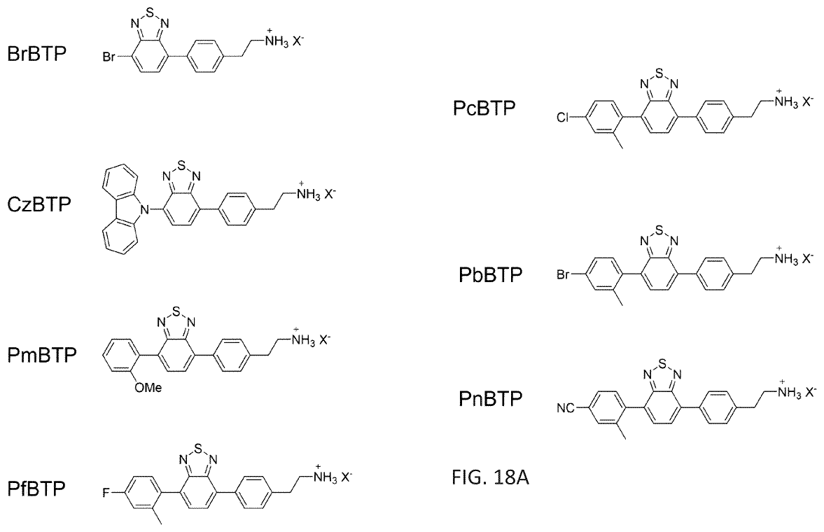

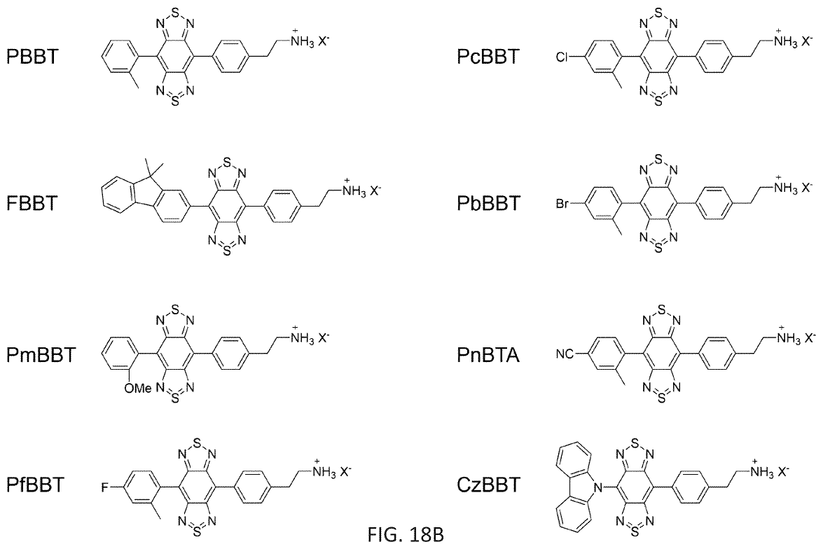

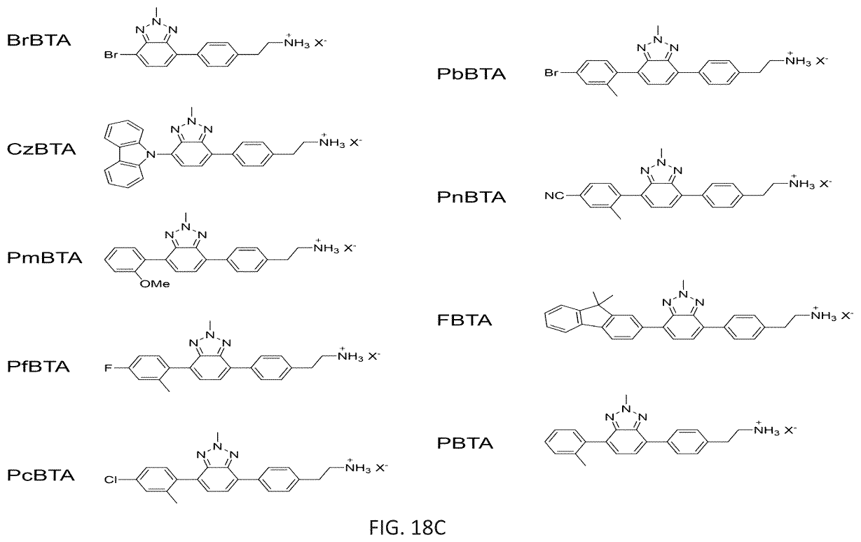

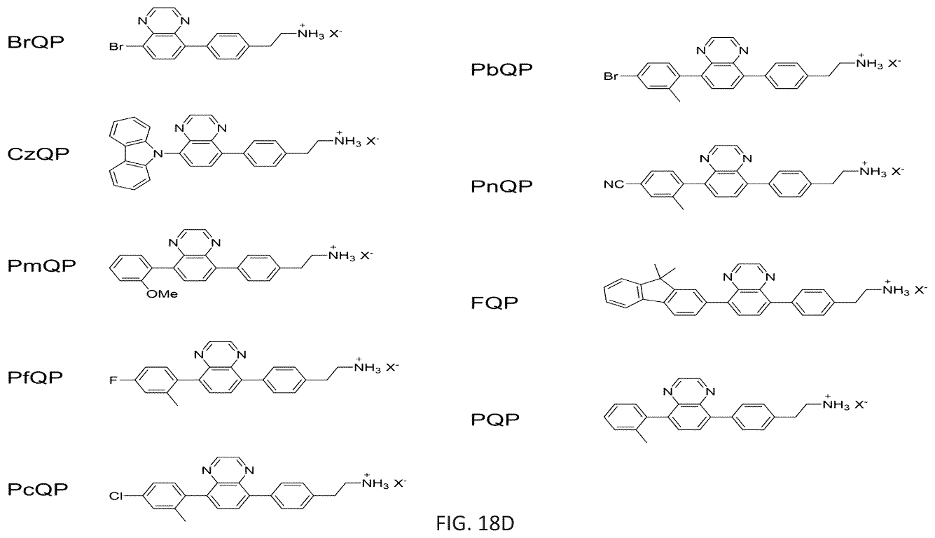

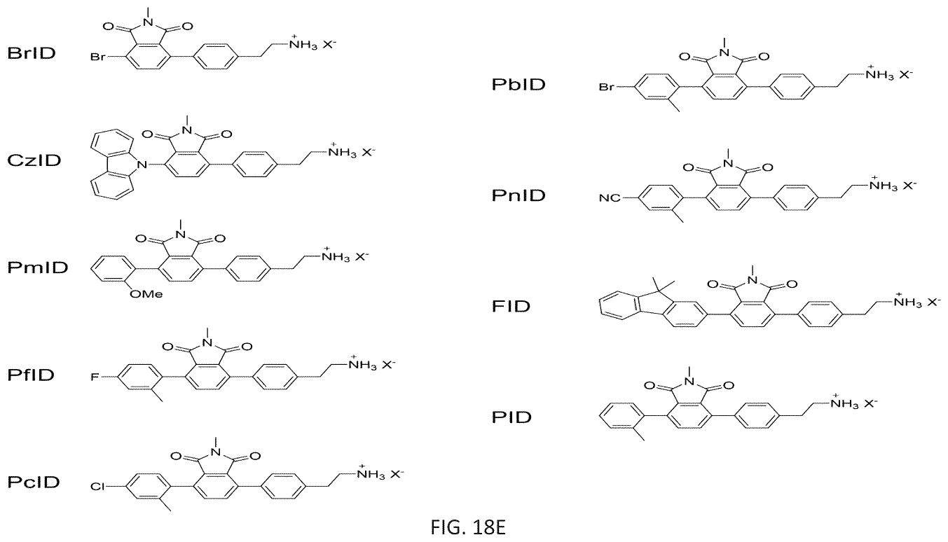

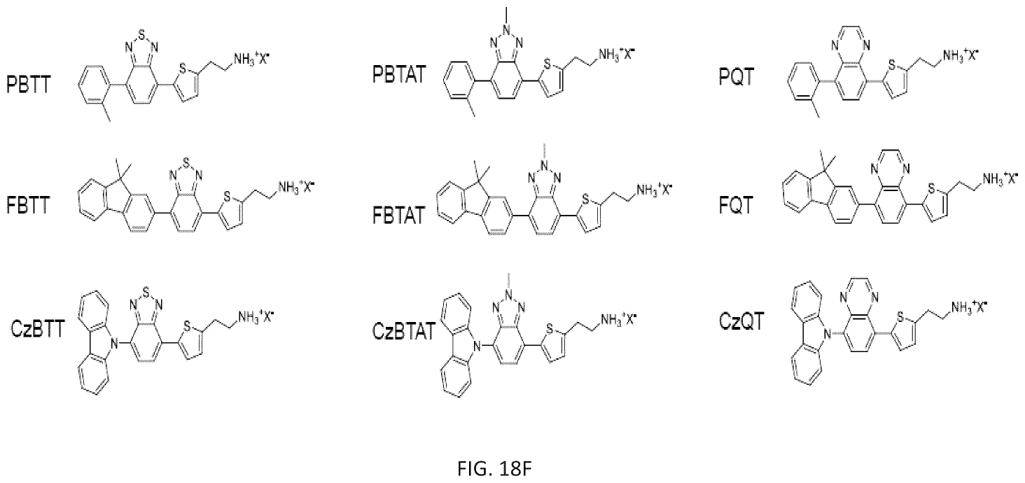

FIGS. 18A-18E show other examples of organic molecular emitters that may be used in addition to or instead of the emitters described above. The organic molecular emitters include one or more of:
2-(5-(7-(9,9-dimethyl-9H-fluoren-2-yl)benzo[c][1,2,5]thiadiazol-4-yl)thiophen-2-yl)ethan-1-ammonium bromide (FBTT),
2-(4-(7-(9,9-dimethyl-9H-fluoren-2-yl)benzo[c][1,2,5]thiadiazol-4-yl)phenyl)ethan-1-ammonium bromide (FBTP),
2-(4-(7-(o-tolyl)benzo[c][1,2,5]thiadiazol-4-yl)phenyl)ethan-1-ammonium bromide (PBTP),
8-bromobenzo[1,2-c:4,5-c′]bis([1,2,5]thiadiazole-4-yl)phenyl)ethan-1-ammonium bromide (BBTP),
benzothiadiazole (BT) units selected from a group that includes BrBTP, (2-(4-(7-bromobenzo[c][1,2,5]thiadiazol-4-yl)phenyl)ethan-1-ammonium), CzBTP (2-(4-(7-(9H-carbazol-9-yl)benzo[c][1,2,5]thiadiazol-4-yl)phenyl)ethan-1-ammonium), PmBTP (2-(4-(7-(2-methoxyphenyl)benzo[c][1,2,5]thiadiazol-4-yl)phenyl)ethan-1-ammonium), PfBTP (2-(4-(7-(4-fluoro-2-methylphenyl)benzo[c][1,2,5]thiadiazol-4-yl)phenyl)ethan-1-ammonium), PcBTP (2-(4-(7-(4-chloro-2-methylphenyl)benzo[c][1,2,5]thiadiazol-4-yl)phenyl)ethan-1-ammonium), PbBTP (2-(4-(7-(4-bromo-2-methylphenyl)benzo[c][1,2,5]thiadiazol-4-yl)phenyl)ethan-1-ammonium), and PnBTP (2-(4-(7-(4-cyano-2-methylphenyl)benzo[c][1,2,5]thiadiazol-4-yl)phenyl)ethan-1-ammonium), with Cl⁻, Br⁻, and I⁻ as a counteranion (X⁻),
benzobisthiadiazole (BBT) units selected from a group that includes PBBT (2-(4-(7-(o-tolyl)[1,2-c:4,5-c′]bis([1,2,5]thiadiazole-4-yl)phenyl)ethan-1-ammonium), FBBT (2-(5-(7-(9,9-dimethyl-9H-fluoren-2-yl)[1,2-c:4,5-c′]bis([1,2,5]thiadiazole-4-yl)phenyl)ethan-1-ammonium), PmBBT (2-(4-(7-(2-methoxyphenyl)[1,2-c:4,5-c′]bis([1,2,5]thiadiazole-4-yl)phenyl)ethan-1-ammonium), PfBBT (2-(4-(7-(4-fluoro-2-methylphenyl)[1,2-c:4,5-c′]bis([1,2,5]thiadiazole-4-yl)phenyl)ethan-1-ammonium), PcBBT (2-(4-(7-(4-chloro-2-methylphenyl)[1,2-c:4,5-c′]bis([1,2,5]thiadiazole-4-yl)phenyl)ethan-1-ammonium), PbBBT (2-(4-(7-(4-bromo-2-methylphenyl)[1,2-c:4,5-c′]bis([1,2,5]thiadiazole-4-yl)phenyl)ethan-1-ammonium), PnBBT (2-(4-(7-(4-cyano-2-methylphenyl)[1,2-c:4,5-c′]bis([1,2,5]thiadiazole-4-yl)phenyl)ethan-1-ammonium), and CzBBT (2-(4-(7-(9H- carbazol-9-yl)[1,2-c:4,5-c′]bis([1,2,5]thiadiazole-4-yl)phenyl)ethan-1-ammonium), with Cl⁻, Br⁻, and I⁻ as a counteranion (X⁻),
2-methyl-2H-benzo[d][1,2,3]triazole (BTA) units selected from a group that includes BrBTA (2-(4-(7-bromo-2-methyl-2H-benzo[d][1,2,3]triazol-4-yl)phenyl)ethan-1-ammonium), CzBTA (2-(4˜(7-(9H-carbazol-9-yl)-2-methyl-2H-benzo[d][1,2,3]triazol-4-yl)phenyl)ethan-1-ammonium), PmBTA (2-(4-(7-(2-methoxyphenyl)-2-methyl-2H-benzo[d][1,2,3]triazol-4-yl)phenyl)ethan-1-ammonium), PfBTA (2-(4-(7-(4-fluoro-2-methylphenyl)-2-methyl-2H-benzo[d][1,2,3]triazol-4-yl)phenyl)ethan-1-ammonium), PcBTA (2-(4-(7-(4-chloro-2-methylphenyl)-2-methyl-2H-benzo[d][1,2,3]triazol-4-yl)phenyl)ethan-1-ammonium), PbBTA (2-(4-(7-(4-bromo-2-methylphenyl)-2-methyl-2H-benzo[d][1,2,3]triazol-4-yl)phenyl)ethan-1-ammonium), PnBTA (2-(4-(7-(4-cyano-2-methylphenyl)-2-methyl-2H-benzo[d][1,2,3]triazol-4-yl)phenyl)ethan-1-ammonium), FBTA (2-(4-(7-(9,9-dimethyl-9H-fluoren-2-yl)-2-methyl-2H-benzo[d][1,2,3]triazol-4-yl)phenyl)ethan-1-ammonium), and PBTP (2-(4-(2-methyl-7-(o-tolyl)-2H-benzo[d][1,2,3]triazol-4-yl)phenyl)ethan-1-ammonium), with Cl⁻, Br⁻, and I⁻ as a counteranion (X⁻),
quinoxaline (Q) units selected from a group that includes BrQP (2-(4-(8-bromoquinoxalin-5-yl)phenyl)ethan-1-ammonium), CzQP (2-(4-(8-(9H-carbazol-9-yl)quinoxalin-5-yl)phenyl)ethan-1-ammonium), PmQP (2-(4-(8-(2-methoxyphenyl)quinoxalin-5-yl)phenyl)ethan-1-ammonium), PfQP (2-(4-(8-(4-fluoro-2-methylphenyl)quinoxalin-5-yl)phenyl)ethan-1-ammonium), PcQP (2-(4-(8-(4-chloro-2-methylphenyl)quinoxalin-5-yl)phenyl)ethan-1-ammonium), PbQP (2-(4-(8-(4-bromo-2-methylphenyl)quinoxalin-5-yl)phenyl)ethan-1-ammonium), PnQP (2-(4-(8-(4-cyano-2-methylphenyl)quinoxalin-5-yl)phenyl)ethan-1-ammonium), FQP (2-(4-(8-(9,9-dimethyl-9H-fluoren-2-yl)quinoxalin-5-yl)phenyl)ethan-1-ammonium), and PQP (2-(4-(8-(o-tolyl)quinoxalin-5-yl)phenyl)ethan-1-ammonium), with Cl⁻, Br⁻, and I⁻ as a counteranion (X⁻), and/or
2-methylisoindoline-1,3-dione (ID) units selected from a group that includes BrID (2-(4-(7-bromo-2-methyl-1,3-dioxoisoindolin-4-yl)phenyl)ethan-1-ammonium), CzID (2-(4-(7-(9H-carbazol-9-yl)-2-methyl-1,3-dioxoisoindolin-4-yl)phenyl)ethan-1-ammonium), PmID (2-(4-(7-(2-methoxyphenyl)-2-methyl-1,3-dioxoisoindolin-4-yl)phenyl)ethan-1-ammonium), PfID (2-(4-(7-(4-fluoro-2-methylphenyl)-2-methyl-1,3-dioxoisoindolin-4-yl)phenyl)ethan-1-ammonium), PcID (2-(4-(7-(4-chloro-2-methylphenyl)-2-methyl-1,3-dioxoisoindolin-4-yl)phenyl)ethan-1-ammonium), PbID (2-(4-(7-(4-bromo-2-methylphenyl)-2-methyl-1,3-dioxoisoindolin-4-yl)phenyl)ethan-1-ammonium), PnID (2-(4-(7-(4-cyano-2-methylphenyl)-2-methyl-1,3-dioxoisoindolin-4-yl)phenyl)ethan-1-ammonium), FID (2-(4-(7-(9,9-dimethyl-9H-fluoren-2-yl)-2-methyl-1,3-dioxoisoindolin-4-yl)phenyl)ethan-1-ammonium), and PID (2-(4-(2-methyl-1,3-dioxo-7-(o-tolyl)isoindolin-4-yl)phenyl)ethan-1-ammonium), with Cl⁻, Br⁻, and I⁻ as a counteranion (X⁻).

As above, a broad class of organic molecular emitters suitable for incorporation into 2D perovskite superlattices to form SMAs is provided. The ability of a given organic cation to support the SMA phase depends on its molecular structure, including the nature of its conjugated core, linker, and ionic head group. The set of representative chemical structures of FIGS. 18A-18E are categorized as positive examples for SMA formation. FIG. 18F shows negative examples for SMA formation. These examples provide guidance for the selection and design of organic emitters that are compatible with the superlattice architecture and capable of achieving the desired photophysical properties. The positive examples represent organic cations that, based on experimental results and/or theoretical considerations, are capable of being incorporated into the 2D perovskite lattice and supporting the SMA phase. These structures typically feature a conjugated aromatic or heteroaromatic core, a suitable linker (such as phenyl, thienyl, or tolyl), and an ammonium or similar cationic group that enables ionic bonding to the inorganic sublattice. The negative examples, by contrast, represent structures that do not support the SMA phase under the tested conditions, often due to excessive planarity, size incompatibility, or a propensity for strong ACQ.

### Positive Examples in SMAs

BrBTP, or 2-(4-(7-bromobenzo[c][1,2,5]thiadiazol-4-yl)phenyl)ethan-1-ammonium, is an organic cation featuring a benzothiadiazole core substituted with a bromine atom at the 7-position. The core is connected via a para-phenylene linker to an ethan-1-ammonium group. The presence of the benzothiadiazole unit provides a strong electron-accepting character, while the phenylene linker imparts rigidity and maintains a suitable molecular width for incorporation into the perovskite lattice. The ammonium group enables ionic bonding to the inorganic sublattice. BrBTP is compatible with the SMA phase due to its balanced planarity and conjugation, which allow for electronic isolation within the superlattice while maintaining efficient emission.

CzBTP, or 2-(4-(7-(9H-carbazol-9-yl)benzo[c][1,2,5]thiadiazol-4-yl)phenyl)ethan-1-ammonium, incorporates a carbazole substituent at the 7-position of the benzothiadiazole core. The carbazole moiety is a well-known electron donor, and its inclusion modulates the electronic properties of the emitter. The structure retains the para-phenylene linker and ethan-1-ammonium group, ensuring compatibility with the perovskite lattice. The combination of donor (carbazole) and acceptor (benzothiadiazole) units, along with the appropriate molecular dimensions, supports the formation of the SMA phase with tunable emission characteristics.

### PmBTP, PfBTP, PcBTP, PbBTP, PnBTP

These structures are all derivatives of the BTP (benzo[c][1,2,5]thiadiazole-phenyl-ethan-1-ammonium) scaffold, differing in the substituent at the 7-position of the benzothiadiazole core: PmBTP: 2-methoxyphenyl substituent, PfBTP: 4-fluoro-2-methylphenyl substituent, PcBTP: 4-chloro-2-methylphenyl substituent, PbBTP: 4-bromo-2-methylphenyl substituent, PnBTP: 4-cyano-2-methylphenyl substituent

Each of these substituents modulates the electronic properties and steric profile of the molecule, allowing for fine-tuning of emission wavelength and aggregation behavior. The para-phenylene linker and ammonium group are retained, ensuring lattice compatibility. These derivatives are positive examples for SMA formation due to their ability to balance conjugation, planarity, and steric effects, resulting in efficient emission and electronic isolation within the superlattice.

### PfBBT, PBBT, FBBT, PmBBT, CzBBT, PcBBT, PbBBT

These compounds are based on the benzobisthiadiazole (BBT) core, which is a stronger electron acceptor than benzothiadiazole. The BBT core is substituted at the 7-position with various groups (e.g., 4-fluoro-2-methylphenyl for PfBBT, o-tolyl for PBBT, 9,9-dimethylfluoren-2-yl for FBBT, 2-methoxyphenyl for PmBBT, carbazol-9-yl for CzBBT, 4-chloro-2-methylphenyl for PcBBT, and 4-bromo-2-methylphenyl for PbBBT). Each structure includes a phenylene linker and an ethan-1-ammonium group. The increased acceptor strength of the BBT core, combined with the tunable substituents, allows for emission across a broad spectral range and supports SMA formation by maintaining appropriate molecular dimensions and electronic properties.

### BrBTA, CzBTA, PmBTA, PfBTA, PcBTA, PbBTA, PnBTA, FBTA, PBTA

These examples are based on the benzo[d][1,2,3]triazole (BTA) core, with various substituents at the 7-position (e.g., bromo, carbazol-9-yl, 2-methoxyphenyl, 4-fluoro-2-methylphenyl, 4-chloro-2-methylphenyl, 4-bromo-2-methylphenyl, 4-cyano-2-methylphenyl, 9,9-dimethylfluoren-2-yl, o-tolyl). The BTA core is less electron-deficient than BBT, providing a different balance of donor-acceptor character. The phenylene linker and ammonium group are present in all cases. These structures are positive examples due to their ability to be incorporated into the superlattice and to support efficient, tunable emission with suppressed aggregation-caused quenching.

### BrQP, CzQP, PmQP, PfQP, PcQP, PbQP, PnQP, FQP, PQP

These compounds are based on the quinoxaline (QP) core, with various substituents at the 8-position (e.g., bromo, carbazol-9-yl, 2-methoxyphenyl, 4-fluoro-2-methylphenyl, 4-chloro-2-methylphenyl, 4-bromo-2-methylphenyl, 4-cyano-2-methylphenyl, 9,9-dimethylfluoren-2-yl, o-tolyl). The QP core provides a different electronic environment, and the substituents allow for further tuning. The phenylene linker and ammonium group are retained. These structures are positive examples for SMA formation due to their compatibility with the lattice and their ability to support high PLQY and directional emission.

### BrID, CzID, PmID, PfID, PcID, PbID, PnID, FID, PID

These examples are based on the 2-methylisoindoline-1,3-dione (ID) core, with various substituents at the 7-position (e.g., bromo, carbazol-9-yl, 2-methoxyphenyl, 4-fluoro-2-methylphenyl, 4-chloro-2-methylphenyl, 4-bromo-2-methylphenyl, 4-cyano-2-methylphenyl, 9,9-dimethylfluoren-2-yl, o-tolyl). The ID core is a strong electron acceptor, and the substituents modulate the emission properties. The phenylene linker and ammonium group are present. These structures are positive examples due to their ability to be incorporated into the superlattice and to support the SMA phase with desirable photophysical properties.

### Negative Examples in SMAs (FIG. 18F)

### PBTT, FBTT, CzBTT

These structures are based on the benzothiadiazole-thienyl-ethan-1-ammonium (BTT) scaffold, with various substituents (e.g., o-tolyl for PBTT, 9,9-dimethylfluoren-2-yl for FBTT, carbazol-9-yl for CzBTT). The thienyl linker, while providing conjugation, can result in excessive planarity and strong-n stacking interactions. This leads to a propensity for aggregation-caused quenching and prevents the formation of the SMA phase under typical conditions. These structures are negative examples because hey do not maintain sufficient electronic isolation within the superlattice.

### PBTA, FBTA, CzBTA

These are BTA-based structures with thienyl linkers and various substituents. Similar to the BTT series, the thienyl linker can promote strong aggregation and quenching, making these structures incompatible with SMA formation.

### PQT, FQT, CzQT

These are quinoxaline-thienyl-ethan-1-ammonium (QT) derivatives with various substituents. The combination of the quinoxaline core and thienyl linker can result in excessive planarity and aggregation, leading to poor emission properties and failure to support the SMA phase.

Accordingly, a new class of 2D hybrid materials is introduced that combine organic and inorganic components in a layered superlattice structure. In these materials. organic molecular emitters are confined between inorganic sheets, forming a periodic arrangement with a precisely controlled spacing. This architecture enables the organic emitters to be held in close proximity yet remain electronically isolated from one another due to the presence of the inorganic layers. The layered superlattice structure uses a SMA phase of matter in which the organic emitters exhibit photophysical properties that closely resemble those of isolated single molecules, such as high photoluminescence quantum yield and narrow emission spectra, while simultaneously displaying collective behaviors typically associated with molecular aggregates, such as strong alignment and directional emission.

This is achieved by engineering the spacing and orientation of the organic emitters within the superlattice, which can be tuned by adjusting the composition and structure of the inorganic sublattice. Methods for fabricating the 2D superlattice materials include the preparation of thin films and single crystals, as well as techniques for incorporating a wide variety of organic emitters into the superlattice framework. Optoelectronic devices that include the 2D superlattice materials as active layers include light-emitting diodes, lasers, and photodetectors, among others.

### EXAMPLES

Example 1 is a two-dimensional (2D) perovskite superlattice comprising inorganic lead-halide sheets having a pitch of approximately about 5 Å to about 8 Å that form a 2D inorganic sublattice, the pitch tunable by selection of a halide composition of the lead-halide sheets, and organic molecular emitters incorporated between the inorganic lead-halide sheets to form the 2D perovskite superlattice having a structure of L₂MX₄, where L is an organic cation, M is a metal cation, and X is a halide, the organic molecular emitters forming a single-molecule-like aggregate (SMA), wherein the organic molecular emitters are electronically isolated within the superlattice and the superlattice exhibits a photoluminescence quantum yield (PLQY) of at least 80% and a directional emission profile.

In example 2, the subject matter of example 1 includes the inorganic lead-halide sheets comprising a metal halide, where a metal is selected from Pb²⁺, Sn²⁺, Ge²⁺, Cu²⁺, Zn²⁺, Cd²⁺, Hg²⁺, Mn²⁺, Fe²⁺, Ni²⁺, Cr²⁺, V²⁺, Pd²⁺, Pt²⁺, or a combination thereof, and the halide is selected from F, Cl, Br, I, or a combination thereof.

In example 3, the subject matter of examples 1-2 includes the inorganic lead-halide sheets providing a reversed type-I band alignment for the organic molecular emitters.

In example 4, the subject matter of examples 1-3 includes the organic molecular emitters comprising 2-(5-(7-(9,9-dimethyl-9H-fluoren-2-yl)benzo[c][1,2,5]thiadiazol-4-yl)thiophen-2-yl)ethan-1-ammonium bromide (FBTT).

In example 5, the subject matter of examples 1-4 includes the organic molecular emitters comprising 2-(4-(7-(9,9-dimethyl-9H-fluoren-2-yl)benzo[c][1,2,5]thiadiazol-4-yl)phenyl)ethan-1-ammonium bromide (FBTP).

In example 6, the subject matter of examples 1-5 includes the organic molecular emitters comprising 2-(4-(7-(o-tolyl)benzo[c][1,2,5]thiadiazol-4-yl)phenyl)ethan-1-ammonium bromide (PBTP).

In example 7, the subject matter of examples 1-6 includes the organic molecular emitters comprising 8-bromobenzo[1,2-c:4,5-c′]bis([1,2,5]thiadiazole-4-yl)phenyl)ethan-1-ammonium bromide (BBTP).

In example 8, the subject matter of examples 1-7 includes the organic molecular emitters comprising benzothiadiazole (BT) units selected from a group that includes BrBTP, CzBTP, PmBTP, PfBTP, PcBTP, PbBTP, and PnBTP, with Cl⁻, Br⁻, and I⁻ as a counteranion (X⁻).

In example 9, the subject matter of examples 1-8 includes the organic molecular emitters comprising benzobisthiadiazole (BBT) units selected from a group that includes PBBT, FBBT, PmBBT, PfBBT, PcBBT, PbBBT, PnBBT, and CzBBT, with Cl⁻, Br⁻, and I⁻ as a counteranion (X⁻).

In example 10, the subject matter of examples 1-9 includes the organic molecular emitters comprising 2-methyl-2H-benzo[d][1,2,3]triazole (BTA) units selected from a group that includes BrBTA, CzBTA, PmBTA, PfBTA, PcBTA, PbBTA, PnBTA, FBTA, and PBTP, with Cl⁻, Br⁻, and I⁻ as a counteranion (X⁻).

In example 11, the subject matter of examples 1-10 includes the organic molecular emitters (L) comprising quinoxaline (Q) units selected from a group that includes BrQP, CzQP, PmQP, PfQP, PcQP, PbQP, PnQP, FQP, and PQP, with Cl⁻, Br⁻, and I⁻ as a counteranion (X⁻).

In example 12, the subject matter of examples 1-11 includes the organic molecular emitters (L) comprising 2-methylisoindoline-1,3-dione (ID) units selected from a group that includes BrID, CzID, PmID, PfID, PcID, PbID, PnID, FID, and PID, with Cl⁻, Br⁻, and I⁻ as a counteranion (X⁻).

In example 13, the subject matter of examples 1-12 includes the organic molecular emitters comprising an organic cation having a conjugated chromophore core, a linker group, and an ammonium tail, the chromophore core selected from benzothiadiazole, benzobisthiadiazole, benzo[d][1,2,3]triazole, quinoxaline, isoindoline-dione, or derivatives thereof, and the linker group selected from phenyl, thienyl, tolyl, or combinations thereof.

Example 14 is an optoelectronic device comprising a two-dimensional (2D) perovskite superlattice as described in example 1, and circuitry configured to provide power to the 2D perovskite superlattice to emit light, wherein the organic molecular emitters are electronically isolated within the superlattice and exhibit a photoluminescence quantum yield (PLQY) of at least 80% and directional emission.

In example 15, the subject matter of example 14 includes the inorganic lead-halide sheets comprising a metal halide.

In example 16, the subject matter of examples 14-15 includes the organic molecular emitters comprising at least one of FBTT, FBTP, PBTP, BBTP, BT units as described in example 8, BBT units as described in example 9, BTA units as described in example 10, Q units as described in example 11, or ID units as described in example 12.

In example 17, the subject matter of examples 14-16 includes the optoelectronic device comprising a laser, and the laser comprising two distributed Bragg reflectors (DBRs) sandwiching the 2D perovskite superlattice.

In example 18, the subject matter of examples 14-17 includes the optoelectronic device comprising a light-emitting diode exhibiting an external quantum efficiency at least 50 times greater than a device comprising the organic molecular emitters in an aggregate state.

Example 19 is a method comprising providing inorganic lead-halide sheets having a pitch of about 5 Å to about 8 Å to form a 2D inorganic sublattice, and incorporating organic molecular emitters between the inorganic lead-halide sheets, the organic molecular emitters comprising at least one of FBTT, FBTP, PBTP, or BBTP.

In example 20, the subject matter of example 19 includes the inorganic lead-halide sheets comprising a metal halide.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to indicate one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. As indicated herein, although the term “a” is used herein, one or more of the associated elements may be used in different embodiments. For example, the term “a processor” configured to carry out specific operations includes both a single processor configured to carry out all of the operations as well as multiple processors individually configured to carry out some or all of the operations (which may overlap) such that the combination of processors carry out all of the operations. Further, the term “includes” may be considered to be interpreted as “includes at least” the elements that follow.

The Abstract of the Disclosure is submitted with the understanding that it will not be used to interpret or limit the scope or meaning of the claims. In addition, in the foregoing Detailed Description, it may be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A two-dimensional (2D) perovskite superlattice comprising:
inorganic lead-halide sheets having a pitch of approximately about 5 Å to about 8 Å that form a 2D inorganic sublattice, the pitch tunable by selection of a halide composition of the inorganic lead-halide sheets; and
organic molecular emitters incorporated between the inorganic lead-halide sheets to form the 2D perovskite superlattice having a structure of L₂MX₄, where L is an organic cation, M is a metal cation, and X is a halide, the organic molecular emitters forming a single-molecule-like aggregate (SMA),
wherein the organic molecular emitters are electronically isolated within the 2D perovskite superlattice and the 2D perovskite superlattice exhibits a photoluminescence quantum yield (PLQY) of at least 80% and directional emission profile.

2. The 2D perovskite superlattice of claim 1, wherein the inorganic lead-halide sheets comprise metal halide, where a metal is selected from Pb²⁺, Sn²⁺, Ge²⁺, Cu²⁺, Zn²⁺, Cd²⁺, Hg²⁺, Mn²⁺, Fe²⁺, Ni²⁺, Cr²⁺, V²⁺, Pd²⁺, Pt²⁺, or a combination of thereof, and the halide is selected from F, Cl, Br, I, or a combination thereof.

3. The 2D perovskite superlattice of claim 1, wherein the inorganic lead-halide sheets provide a reversed type-I band alignment for the organic molecular emitters.

4. The 2D perovskite superlattice of claim 1, wherein the organic molecular emitters comprise 2-(5-(7-(9,9-dimethyl-9H-fluoren-2-yl)benzo[c][1,2,5]thiadiazol-4-yl)thiophen-2-yl)ethan-1-ammonium bromide (FBTT).

5. The 2D perovskite superlattice of claim 1, wherein the organic molecular emitters comprise 2-(4-(7-(9,9-dimethyl-9H-fluoren-2-yl)benzo[c][1,2,5]thiadiazol-4-yl)phenyl)ethan-1-ammonium bromide (FBTP).

6. The 2D perovskite superlattice of claim 1, wherein the organic molecular emitters comprise 2-(4-(7-(o-tolyl)benzo[c][1,2,5]thiadiazol-4-yl)phenylethan-1-ammonium bromide (PBTP).

7. The 2D perovskite superlattice of claim 1, wherein the organic molecular emitters comprise 8-bromobenzo[1,2-c:4,5-c′]bis([1,2,5]thiadiazole-4-yl)phenyl)ethan-1-ammonium bromide (BBTP).

8. The 2D perovskite superlattice of claim 1, wherein the organic molecular emitters comprise benzothiadiazole (BT) units selected from a group that includes BrBTP (2-(4-(7-bromobenzo[c][1,2,5]thiadiazol-4-yl)phenyl)ethan-1-ammonium), CzBTP (2-(4-(7-(9H-carbazol-9-yl)benzo[c][1,2,5]thiadiazol-4-yl)phenyl)ethan-1-ammonium), PmBTP (2-(4-(7-(2-methoxyphenyl)benzo[c][1,2,5]thiadiazol-4-yl)phenyl)ethan-1-ammonium), PfBTP (2-(4-(7-(4-fluoro-2-methylphenyl)benzo[c][1,2,5]thiadiazol-4-yl)phenyl)ethan-1-ammonium), PcBTP (2-(4-(7-(4-chloro-2-methylphenyl)benzo[c][1,2,5]thiadiazol-4-yl)phenyl)ethan-1-ammonium), PbBTP (2-(4-(7-(4-bromo-2-methylphenyl)benzo[c][1,2,5]thiadiazol-4-yl)phenyl)ethan-1-ammonium), and PnBTP (2-(4-(7-(4-cyano-2-methylphenyl)benzo[c][1,2,5]thiadiazol-4-yl)phenyl)ethan-1-ammonium), with Cl⁻, Br⁻, and I⁻ as a counteranion (X⁻).

9. The 2D perovskite superlattice of claim 1, wherein the organic molecular emitters comprise benzobisthiadiazole (BBT) units selected from a group that includes PBBT (2-(4-(7-(o-tolyl)[1,2-c:4,5-c′]bis([1,2,5]thiadiazole-4-yl)phenyl)ethan-1-ammonium), FBBT (2-(5-(7-(9,9-dimethyl-9H-fluoren-2-yl)[1,2-c:4,5-c′]bis([1,2,5]thiadiazole-4-yl)phenyl)ethan-1-ammonium), PmBBT (2-(4-(7-(2-methoxyphenyl)[1,2-c:4,5-c′]bis([1,2,5]thiadiazole-4-yl)phenyl)ethan-1-ammonium), PfBBT (2-(4-(7-(4-fluoro-2-methylphenyl)[1,2-c:4,5-c′]bis([1,2,5]thiadiazole-4-yl)phenyl)ethan-1-ammonium), PcBBT (2-(4-(7-(4-chloro-2-methylphenyl)[1,2-c:4,5-c′]bis([1,2,5]thiadiazole-4-yl)phenyl)ethan-1-ammonium), PbBBT (2-(4-(7-(4-bromo-2-methylphenyl)[1,2-c:4,5-c′]bis([1,2,5]thiadiazole-4-yl)phenyl)ethan-1-ammonium), PnBBT (2-(4-(7-(4-cyano-2-methylphenyl)[1,2-c:4,5-c′]bis([1,2,5]thiadiazole-4-yl)phenyl)ethan-1-ammonium), and CzBBT (2-(4-(7˜(9H-carbazol-9-yl)[1,2-c:4,5-c′]bis([1,2,5]thiadiazole-4-yl)phenyl)ethan-1-ammonium), with Cl⁻, Br⁻, and I⁻ as a counteranion (X⁻).

10. The 2D perovskite superlattice of claim 1, wherein the organic molecular emitters comprise 2-methyl-2H-benzo[d][1,2,3]triazole (BTA) units selected from a group that includes BrBTA (2-(4-(7-bromo-2-methyl-2H-benzo[d][1,2,3]triazol-4-yl)phenyl)ethan-1-ammonium), CzBTA (2-(4-(7-(9H-carbazol-9-yl)-2-methyl-2H-benzo[d][1,2,3]triazol-4-yl)phenyl)ethan-1-ammonium), PmBTA (2-(4-(7-(2-methoxyphenyl)-2-methyl-2H-benzo[d][1,2,3]triazol-4-yl)phenyl)ethan-1-ammonium), PfBTA (2-(4-(7-(4-fluoro-2-methylphenyl)-2-methyl-2H-benzo[d][1,2,3]triazol-4-yl)phenyl)ethan-1-ammonium), PcBTA (2-(4-(7-(4-chloro-2-methylphenyl)-2-methyl-2H-benzo[d][1,2,3]triazol-4-yl)phenyl)ethan-1-ammonium), PbBTA (2-(4-(7-(4-bromo-2-methylphenyl)-2-methyl-2H-benzo[d][1,2,3]triazol-4-yl)phenyl)ethan-1-ammonium), PnBTA (2-(4-(7-(4-cyano-2-methylphenyl)-2-methyl-2H-benzo[d][1,2,3]triazol-4-yl)phenyl)ethan-1-ammonium), FBTA (2-(4-(7-(9,9-dimethyl-9H-fluoren-2-yl)-2-methyl-2H-benzo[d][1,2,3]triazol-4-yl)phenyl)ethan-1-ammonium), and PBTP (2-(4-(2-methyl-7-(o-tolyl)-2H-benzo[d][1,2,3]triazol-4-yl)phenyl)ethan-1-ammonium), with Cl⁻, Br⁻, and I⁻ as a counteranion (X⁻).

11. The 2D perovskite superlattice of claim 1, wherein the organic molecular emitters (L) comprise quinoxaline (Q) units selected from a group that includes BrQP (2-(4-(8-bromoquinoxalin-5-yl)phenyl)ethan-1-ammonium), CzQP (2-(4-(8-(9H-carbazol-9-yl)quinoxalin-5-yl)phenyl)ethan-1-ammonium), PmQP (2-(4-(8-(2-methoxyphenyl)quinoxalin-5-yl)phenyl)ethan-1-ammonium), PfQP (2-(4-(8-(4-fluoro-2-methylphenyl)quinoxalin-5-yl)phenyl)ethan-1-ammonium), PcQP (2-(4-(8-(4-chloro-2-methylphenyl)quinoxalin-5-yl)phenyl)ethan-1-ammonium), PbQP (2-(4-(8-(4-bromo-2-methylphenyl)quinoxalin-5-yl)phenyl)ethan-1-ammonium), PnQP (2-(4-(8-(4-cyano-2-methylphenyl)quinoxalin-5-yl)phenyl)ethan-1-ammonium), FQP (2-(4-(8-(9,9-dimethyl-9H-fluoren-2-yl)quinoxalin-5-yl)phenyl)ethan-1-ammonium), and PQP (2-(4-(8-(o-tolyl)quinoxalin-5-yl)phenyl)ethan-1-ammonium), with Cl⁻, Br⁻, and I⁻ as a counteranion (X⁻).

12. The 2D perovskite superlattice of claim 1, wherein the organic molecular emitters (L) comprise 2-methylisoindoline-1,3-dione (ID) units selected from a group that includes BrID (2-(4-(7-bromo˜2-methyl-1,3-dioxoisoindolin-4-yl)phenyl)ethan-1-ammonium), CzID (2-(4-(7-(9H-carbazol-9-yl)-2-methyl-1,3-dioxoisoindolin-4-yl)phenyl)ethan-1-ammonium), PmID (2-(4-(7-(2-methoxyphenyl)-2-methyl-1,3-dioxoisoindolin-4-yl)phenyl)ethan-1-ammonium), PfID (2-(4-(7-(4-fluoro-2-methylphenyl)-2-methyl-1,3-dioxoisoindolin-4-yl)phenyl)ethan-1-ammonium), PcID (2-(4-(7-(4-chloro-2-methylphenyl)-2-methyl-1,3-dioxoisoindolin-4-yl)phenyl)ethan-1-ammonium), PbID (2-(4-(7-(4-bromo-2-methylphenyl)-2-methyl-1,3-dioxoisoindolin-4-yl)phenyl)ethan-1-ammonium), PnID (2-(4-(7-(4-cyano-2-methylphenyl)-2-methyl-1,3-dioxoisoindolin-4-yl)phenyl)ethan-1-ammonium), FID (2-(4-(7-(9,9-dimethyl-9H-fluoren-2-yl)-2-methyl-1,3-dioxoisoindolin-4-yl)phenyl)ethan-1-ammonium), and PID (2-(4-(2-methyl-1,3-dioxo-7-(o-tolyl)isoindolin-4-yl)phenyl)ethan-1-ammonium), with Cl⁻, Br⁻, and I⁻ as a counteranion (X⁻).

13. The 2D perovskite superlattice of claim 1, wherein the organic molecular emitters comprise an organic cation having a conjugated chromophore core, a linker group, and an ammonium tail, the conjugated chromophore core selected from benzothiadiazole, benzobisthiadiazole, benzo[d][1,2,3]triazole, quinoxaline, isoindoline-dione, or derivatives thereof, and the linker group selected from phenyl, thienyl, tolyl, or combinations thereof.

14. An optoelectronic device comprising:
a two-dimensional (2D) perovskite superlattice comprising:
inorganic lead-halide sheets having a pitch of approximately about 5 Å to about 8 Å that form a 2D inorganic sublattice, the pitch tunable by selection of a halide composition of the inorganic lead-halide sheets; and
organic molecular emitters incorporated between the inorganic lead-halide sheets to form the 2D perovskite superlattice having a structure of L₂MX₄, where L is an organic cation, M is a metal cation, and X is a halide, the organic molecular emitters forming a single-molecule-like aggregate (SMA); and
circuitry configured to provide power to the 2D perovskite superlattice to emit light,
wherein the organic molecular emitters are electronically isolated within the 2D perovskite superlattice and exhibit a photoluminescence quantum yield (PLQY) of at least 80% and directional emission.

15. The optoelectronic device of claim 14, wherein the inorganic lead-halide sheets comprise a metal halide.

16. The optoelectronic device of claim 14, wherein the organic molecular emitters comprise at least one of:
2-(5-(7-(9,9-dimethyl-9H-fluoren-2-yl)benzo[c][1,2,5]thiadiazol-4-yl)thiophen-2-yl)ethan-1-ammonium bromide (FBTT),
2-(4-(7-(9,9-dimethyl-9H-fluoren-2-yl)benzo[c][1,2,5]thiadiazol-4-yl)phenyl)ethan-1-ammonium bromide (FBTP),
2-(4-(7-(o-tolyl)benzo[c][1,2,5]thiadiazol-4-yl)phenyl)ethan-1-ammonium bromide (PBTP),
8-bromobenzo[1,2˜c:4,5-c′]bis([1,2,5]thiadiazole-4-yl)phenyl)ethan-1-ammonium bromide (BBTP),
benzothiadiazole (BT) units selected from a group that includes BrBTP (2-(4-(7-bromobenzo[c][1,2,5]thiadiazol-4-yl)phenyl)ethan-1-ammonium), CzBTP (2-(4-(7-(9H-carbazol-9-yl)benzo[c][1,2,5]thiadiazol-4-yl)phenyl)ethan-1-ammonium), PmBTP (2-(4-(7-(2-methoxyphenyl)benzo[c][1,2,5]thiadiazol-4-yl)phenyl)ethan-1-ammonium), PfBTP (2-(4-(7-(4-fluoro-2-methylphenyl)benzo[c][1,2,5]thiadiazol-4-yl)phenyl)ethan-1-ammonium), PcBTP (2-(4-(7-(4-chloro-2-methylphenyl)benzo[c][1,2,5]thiadiazol-4-yl)phenyl)ethan-1-ammonium), PbBTP (2-(4-(7-(4-bromo-2-methylphenyl)benzo[c][1,2,5]thiadiazol-4-yl)phenyl)ethan-1-ammonium), and PnBTP (2-(4-(7-(4-cyano-2-methylphenyl)benzo[c][1,2,5]thiadiazol-4-yl)phenyl)ethan-1-ammonium), with Cl⁻, Br⁻, and I⁻ as a counteranion (X⁻),
benzobisthiadiazole (BBT) units selected from a group that includes PBBT (2-(4-(7-(o-tolyl)[1,2-c:4,5-c′]bis([1,2,5]thiadiazole-4-yl)phenyl)ethan-1-ammonium), FBBT (2-(5-(7-(9,9-dimethyl-9H-fluoren-2-yl)[1,2-c:4,5-c′]bis([1,2,5]thiadiazole-4-yl)phenyl)ethan-1-ammonium), PmBBT (2-(4-(7-(2-methoxyphenyl)[1,2-c:4,5-c′]bis([1,2,5]thiadiazole-4-yl)phenyl)ethan-1-ammonium), PfBBT (2-(4-(7-(4-fluoro-2-methylphenyl)[1,2-c:4,5-c′]bis([1,2,5]thiadiazole-4-yl)phenyl)ethan-1-ammonium), PcBBT (2-(4-(7-(4-chloro-2-methylphenyl)[1,2-c:4,5-c′]bis([1,2,5]thiadiazole-4-yl)phenyl)ethan-1-ammonium), PbBBT (2-(4-(7-(4-bromo-2-methylphenyl)[1,2-c:4,5-c′]bis([1,2,5]thiadiazole-4-yl)phenyl)ethan-1-ammonium), PnBBT (2-(4-(7-(4-cyano-2-methylphenyl)[1,2-c:4,5-c′]bis([1,2,5]thiadiazole-4-yl)phenyl)ethan-1-ammonium), and CzBBT (2-(4-(7-(9H-carbazol-9-yl)[1,2-c:4,5-c′]bis([1,2,5]thiadiazole-4-yl)phenyl)ethan-1-ammonium), with Cl⁻, Br⁻, and I⁻ as a counteranion (X⁻),
2-methyl-2H-benzo[d][1,2,3]triazole (BTA) units selected from a group that includes BrBTA (2-(4-(7-bromo-2-methyl-2H-benzo[d][1,2,3]triazol-4-yl)phenyl)ethan-1-ammonium), CzBTA (2-(4-(7-(9H-carbazol-9-yl)-2-methyl-2H-benzo[d][1,2,3]triazol-4-yl)phenyl)ethan-1-ammonium), PmBTA (2-(4-(7-(2-methoxyphenyl)-2-methyl-2H-benzo[d][1,2,3]triazol-4-yl)phenyl)ethan-1-ammonium), PfBTA (2-(4-(7-(4-fluoro-2-methylphenyl)-2-methyl-2H-benzo[d][1,2,3]triazol-4-yl)phenyl)ethan-1-ammonium), PcBTA (2-(4-(7-(4-chloro-2-methylphenyl)-2-methyl-2H-benzo[d][1,2,3]triazol-4-yl)phenyl)ethan-1-ammonium), PbBTA (2-(4-(7-(4-bromo˜2-methylphenyl)-2-methyl-2H-benzo[d][1,2,3]triazol-4-yl)phenyl)ethan-1-ammonium), PnBTA (2-(4-(7-(4-cyano-2-methylphenyl)-2-methyl-2H-benzo[d][1,2,3]triazol-4-yl)phenyl)ethan-1-ammonium), FBTA (2-(4-(7-(9,9-dimethyl-9H-fluoren-2-yl)-2-methyl-2H-benzo[d][1,2,3]triazol-4-yl)phenyl)ethan-1-ammonium), and PBTP (2-(4-(2-methyl-7-(o-tolyl)-2H-benzo[d][1,2,3]triazol-4-yl)phenyl)ethan-1-ammonium), with Cl⁻, Br⁻, and I⁻ as a counteranion (X⁻),
quinoxaline (Q) units selected from a group that includes BrQP (2-(4-(8-bromoquinoxalin-5-yl)phenyl)ethan-1-ammonium), CzQP (2-(4-(8-(9H-carbazol-9-yl)quinoxalin-5-yl)phenyl)ethan-1-ammonium), PmQP (2-(4-(8-(2-methoxyphenyl)quinoxalin-5-yl)phenyl)ethan-1-ammonium), PfQP (2-(4-(8-(4-fluoro-2-methylphenyl)quinoxalin-5-yl)phenyl)ethan-1-ammonium), PcQP (2-(4-(8-(4-chloro-2-methylphenyl)quinoxalin-5-yl)phenyl)ethan-1-ammonium), PbQP (2-(4-(8-(4-bromo-2-methylphenyl)quinoxalin-5-yl)phenyl)ethan-1-ammonium), PnQP (2-(4-(8-(4-cyano-2-methylphenyl)quinoxalin-5-yl)phenyl)ethan-1-ammonium), FQP (2-(4-(8-(9,9-dimethyl-9H-fluoren-2-yl)quinoxalin-5-yl)phenyl)ethan-1-ammonium), and PQP (2-(4-(8-(o-tolyl)quinoxalin-S-yl)phenyl)ethan-1-ammonium), with Cl⁻, Br⁻, and I⁻ as a counteranion (X⁻), or
2-methylisoindoline-1,3-dione (ID) units selected from a group that includes BrID (2-(4-(7-bromo-2-methyl-1,3-dioxoisoindolin-4-yl)phenyl)ethan-1-ammonium), CzID (2-(4-(7-(9H-carbazol-9-yl)-2-methyl-1,3-dioxoisoindolin-4-yl)phenyl)ethan-1-ammonium), PmID (2-(4-(7-(2-methoxyphenyl)-2-methyl-1,3-dioxoisoindolin-4-yl)phenyl)ethan-1-ammonium), PfID (2-(4-(7-(4-fluoro-2-methylphenyl)-2-methyl-1,3-dioxoisoindolin-4-yl)phenyl)ethan-1-ammonium), PcID (2-(4-(7-(4-chloro-2-methylphenyl)-2-methyl-1,3-dioxoisoindolin-4-yl)phenyl)ethan-1-ammonium), PbID (2-(4-(7-(4-bromo-2-methylphenyl)-2-methyl-1,3-dioxoisoindolin-4-yl)phenyl)ethan-1-ammonium), PnID (2-(4-(7-(4-cyano-2-methylphenyl)-2-methyl-1,3-dioxoisoindolin-4-yl)phenyl)ethan-1-ammonium), FID (2-(4-(7-(9,9-dimethyl-9H-fluoren-2-yl)-2-methyl-1,3-dioxoisoindolin-4-yl)phenyl)ethan-1-ammonium), and PID (2-(4-(2-methyl-1,3-dioxo-7-(o-tolyl)isoindolin-4-yl)phenyl)ethan-1-ammonium), with Cl⁻, Br⁻, and I⁻ as a counteranion (X⁻).

17. The optoelectronic device of claim 14, wherein:
the optoelectronic device comprises a laser, and
the laser comprises two distributed Bragg reflectors (DBRs) sandwiching the 2D perovskite superlattice.

18. The optoelectronic device of claim 14, wherein the optoelectronic device comprises a light-emitting diode exhibiting an external quantum efficiency at least 50 times greater than a device comprising the organic molecular emitters in an aggregate state.

19. A method of producing a two-dimensional (2D) perovskite superlattice, the method comprising:
providing inorganic lead-halide sheets having a pitch of about 5 Å to about 8 Å to form a 2D inorganic sublattice; and
incorporating organic molecular emitters between the inorganic lead-halide sheets, the organic molecular emitters comprising at least one of:
2-(5-(7-(9,9-dimethyl-9H-fluoren-2-yl)benzo[c][1,2,5]thiadiazol-4-yl)thiophen-2-ylethan-1-ammonium bromide (FBTT),
2-(4-(7-(9,9-dimethyl-9H-fluoren-2-yl)benzo[c][1,2,5]thiadiazol-4-yl)phenyl)ethan-1-ammonium bromide (FBTP),
2-(4-(7-(o-tolyl)benzo[c][1,2,5]thiadiazol-4-yl)phenyl)ethan-1-ammonium bromide (PBTP), or
8-bromobenzo[1,2-c:4,5-c′]bis([1,2,5]thiadiazole-4˜yl)phenyl)ethan-1-ammonium bromide (BBTP).

20. The method of claim 19, wherein the inorganic lead-halide sheets comprise a metal halide.
